(19) United States
(12) Patent Application Publication
(10) Pub. No.: US 2023/0403912 A1
(43) Pub. Date: Dec. 14, 2023

(54) Light Emitting Devices With Coupled Resonant Photonic Unit Cells and Distributed Light Emitting Diodes

(71) Applicant: UNIVERSITY OF VERMONT AND STATEAGRICULTURAL COLLEGE, Burlington, VT (US)

(72) Inventors: David Allemeier, Burlington, VT (US); Matthew Schuette White, Burlington, VT (US)

(21) Appl. No.: 18/029,309

(22) PCT Filed: Oct. 1, 2021
(86) PCT No.: PCT/US2021/071679

§ 371 Date: Mar. 29, 2023

Related U.S. Application Data
(60) Provisional application No. 63/198,204, filed on Oct. 2, 2020.

(51) Int. Cl. H10K 59/80; H01S 5/40; H01S 5/10; H01S 5/042

(52) U.S. Cl. CPC H10K 59/876; H01S 5/04253; H01S 5/1042; H01S 5/4043

(57) ABSTRACT

Distributed feedback distributed gain light emitting devices that include a plurality of optical gain media including active emitter layers dispersed throughout a distributed feedback structure. In some examples, the distributed feedback structures enable direct electrical stimulation of each of the plurality of emitter layers and constitute a periodic array of high quality factor (high-Q) optical resonator cavities and/or a Bragg-type periodic variation in effective refractive index.

### RELATED APPLICATION DATA

This application claims the benefit of priority of U.S. Provisional Patent Application Ser. No. 63/198,204, filed Oct. 2, 2020, and titled Light Emitting Devices With Coupled Resonant Photonic Unit Cells And Distributed Light Emitting Diodes, which is incorporated by reference herein in its entirety.

### STATEMENT REGARDING FEDERALLY SPONSORED RESEARCH OR DEVELOPMENT

This invention was made with government support under Award Number 1932677 awarded by the National Science Foundation. The government has certain rights in the invention.

### FIELD OF THE DISCLOSURE

The present disclosure generally relates to the field of light emitting devices. In particular, the present disclosure is directed light emitting devices with coupled resonant photonic unit cells and distributed light emitting diodes and methods of using the same.

### BACKGROUND

The microcavity effect has been utilized to control the electrically-driven emission from light emitting diodes such as the broadband organic molecules in an OLED. This effect has been well studied for decades for color tuning, improved efficiency and for the angular emission effects in regular LEDs, OLEDs and laser cavities. A traditional microcavity is a structure consisting of two parallel mirrors on either side of an optical medium. Light is trapped between the two mirrors and interferes with itself to establish a set of resonant modes. Light with a wavelength near one of the resonances can propagate, while light with different wavelength is suppressed. The resonant modes are directly related to the optical path length (OPL) of the optical medium between the two mirrors, where the resonant wavelength must be equal to a half-integer multiple of the OPL,

$$\\ \begin{matrix}{λ}_{j} = \frac{2 * n * d}{j} j = 1 , 2 , 3 , … & Eq . ( 1 )\end{matrix}$$

where n is the index of refraction of the medium, d is the optical medium thickness and j is the mode index. The lowest energy, largest wavelength mode is at j=1—the λ/2 mode—and as j→∞ the energy increases to infinity as well. The emission spectrum is thus made up of an infinite series of resonant modes which start at the λ/2 mode and increases to infinity, where the energy of the λ/2 mode depends directly on the product n*d, which is the OPL of the medium.

FIGS. 20A-20C illustrate example emission characteristics of three different λ/2 microcavities having different OPLs, namely about 180 nm, 220 nm and about 245 nm, due to thicker organic layers, 105 nm, 125 nm, and 145 nm, respectively. In the illustrated example, an OLED with an Alq3 emissive layer (EML) was used with an emission peak 2002 at 550 nm. As shown in FIG. 20A, the 180 nm OPL microcavity has an emission peak 1804 at about 540 nm, approximately matching the peak wavelength of the non-cavity OLED, while the emission peak 2006 of the 220 nm microcavity and the emission peak 2008 of the 245 nm microcavity emit at about 605 nm and 660 nm, respectively. FIG. 20A shows that as the OPL increases, either as a result of thicker organic layers or use of higher index of refraction materials, the emission peak shifts to longer wavelengths, allowing control of the color of the emitted light by shifting the resonant wavelengths and allowing access to higher order (larger j) resonant modes. FIGS. 20B and 20C show experimental results further illustrating control of emission color by increased device thickness. As shown, critical thresholds exist where the emitting mode switches to a higher order as the fundamental mode drops below the emission spectrum of the emitting layer, here Alq3, due to increased thickness. FIG. 20C shows how the Q-factor is dependent on the mode index with higher-order modes possessing increased Q-factor, where the Q-factor is a measure of the width of the peak and efficiency of the resonance. Increasing the microcavity thickness allows the Alq3 emitter to pump higher-order modes by reducing the energy of the modes that directly overlap the Alq3 emission spectrum. These higher-order modes possess an increased Q-factor and hence improved resonance efficiency.

While increasing the thickness of the microcavity can result in improved optical characteristics such as a higher Q-factor, minimizing the thickness of the device can dramatically improve electronic efficiency, particularly for OLEDs due to the high resistivity of the organic materials employed. The tradeoff is that while thinner microcavities result in a substantial reduction in electrical losses, they do not allow access to the higher-order optical modes (j>1) and the corresponding superior optical performance.

### SUMMARY OF THE DISCLOSURE

In one implementation, the present disclosure is directed to light emitting device. The device includes a plurality of active emitter layers dispersed throughout a distributed feedback structure, the distributed feedback structure designed to transmit or reflect light according to the wavelength of the light; and wherein the structure is configured for direct electrical stimulation of each of the emitter layers.

In another implementation, the present disclosure is directed to a light emitting device. The device includes a periodic array of a plurality of optical resonator cavities; and at least one electrically driven emitter layer located in each of the optical resonator cavities.

In yet another implementation, the present disclosure is directed to a light emitting device. The device includes a periodic array of a plurality of microcavities, each of the microcavities including two parallel semitransparent mirrors and an electrically driven emitter located therebetween, wherein the semitransparent mirrors are designed and configured to allow interaction of the resonant modes of adjacent ones of the plurality of microcavities.

In yet another implementation, the present disclosure is directed to a light emitting device. The devices includes a substantially planar substrate; a bottom metallic mirror formed on said substrate; a plurality of photonic unit cells formed vertically on said bottom metallic mirror; and a top metallic mirror formed on said plurality of photonic unit cells; wherein said photonic unit cells comprise one or more microcavities, wherein each of said microcavities is optically emissive in response to applied electrical stimulus, and wherein the optical path length of said microcavities in the direction normal to said planar substrate are chosen to produce a desired photonic band structure.

In yet another implementation, the present disclosure is directed to a light emitting device, comprising. The device includes a substrate; a bottom mirror disposed on said substrate; an alternating series of high and low index materials disposed on said bottom mirror; and a top mirror deposited on said alternating series; and wherein said low index materials are layers of light emitting diodes that are optically emissive in response to electrical stimulus provided through said high index materials.

### BRIEF DESCRIPTION OF THE DRAWINGS

For the purpose of illustrating the disclosure, the drawings show aspects of one or more embodiments of the disclosure. However, it should be understood that the present disclosure is not limited to the precise arrangements and instrumentalities shown in the drawings, wherein:

FIG. 1 illustrates an example distributed feedback distributed gain light emitting device;

FIG. 2 illustrates an example implementation of the device of FIG. 1 and includes a periodic one dimensional array of microcavities separated by reflective and semitransparent electrodes;

FIG. 3 is a detail illustration of one example of two of the emitters and surrounding electrodes of the device of FIG. 2;

FIGS. 4A-4E illustrate example photonic energy bands for photonic structures with 1, 2, 4, and 6 microcavities;

FIG. 5A illustrates the electric field profile of the resonant modes within a single 3λ microcavity;

FIG. 5B illustrates the electric field profile of the resonant modes within the six cavity device of FIG. 2;

FIG. 6A illustrates the photonic band structure for a single 3λ microcavity;

FIG. 6B illustrates the photonic band structure for the six cavity device of FIG. 2;

FIGS. 7A-7D illustrate photonic energy bands for example implementations of the device of FIG. 2 in the form of a six microcavity one-dimensional photonic structure with varying electrode thicknesses;

FIGS. 8A-8C illustrate a perturbation caused by introducing two defects in a six microcavity photonic structure, namely, using a different material for the cathode and anode and varying the thickness of the cathodes;

FIGS. 8D-8G illustrate results from mathematical modeling calculations of example six-microcavity devices with varying aperiodic characteristics;

FIG. 8H shows computationally simulated and experimentally resolved peak positions of the states of the photonic energy band for devices with 1 through 6 microcavities with 15:1 Ag:Al alloy/MoOx as the anode and Al/LiF as the cathode

FIG. 8I shows computationally simulated and experimentally resolved peak positions of the states of the photonic energy band for devices with 1 through 6 microcavities for a device an Ag:Al (15:1) alloy for the anode and Ag—Mg (10:1) alloy for the cathode;

FIG. 8J shows the normalized intensity 820 of the emission of the six cavity Ag:Al device from FIG. 8H and the normalized intensity 822 of the emission of the six cavity Ag—Ag device from FIG. 8I;

FIGS. 9A-9E illustrate relative emission intensity of stacked microcavity devices according to the number of cavities, mirror thickness, and mirror composition;

FIGS. 9F and 9G illustrate the effect of increasing driving voltage on stimulated emission from a six-microcavity OLED stack;

FIG. 10 illustrates a light emitting device that includes a Bragg-type structure having a periodic one dimensional array of photonic unit cells;

FIG. 11 illustrates a light emitting device that includes composite shared electrodes that comprise a transparent and electrically conductive layer sandwiched between two metal layers;

FIG. 12 illustrates a light emitting device that includes at least one outcoupling cavity;

FIGS. 13A-13C illustrate examples of transmission spectroscopy systems that incorporate stacked arrays of microcities made in accordance with the present disclosure for one or more of an emitter and a detector of the system;

FIG. 14 illustrates one example of a reflection spectroscopy or reflection imaging system that incorporates a stacked array of microcities made in accordance with the present disclosure for one or more of an emitter and a detector of the system;

FIG. 15 illustrates one example of an imaging system that incorporates a stacked array of microcities made in accordance with the present disclosure for one or more of an emitter and a detector of the system;

FIGS. 16A-16C illustrate examples of displays or diode arrays that comprise one or two dimensional arrays of light emitting devices, where each light emitting device includes at least one stacked array of microcavities made in accordance with the present disclosure;

FIGS. 17A-17C illustrate three examples of angle-resolved transmission spectroscopy systems that incorporate a stacked array of microcities made in accordance with the present disclosure for one or more of an emitter and a detector of the system;

FIG. 17D illustrates one example of the dispersion exhibited by an example emitter;

FIGS. 17E-G illustrate emission cross sections of three emission spectra: one at 0° (FIG. 17E), one at 50° (FIG. 17F) and then an example of the sum of the two (FIG. 17G); and

FIGS. 18A-18F illustrate a variation in the distribution of photonic states when only one emitter in a six-cavity device is electrically activated;

FIG. 19 illustrates the effect of the number of cavities and mirror thickness on the FWHM of the highest-energy mode of an ideal photonic structure made in accordance with the present disclosure; and

FIGS. 20A-20C illustrate example emission characteristics of three different prior art single microcavities having different OPLs, namely 180 nm, 220 nm and 245 nm, as compared to a non-cavity OLED.

### DETAILED DESCRIPTION

Aspects of the present disclosure include distributed feedback distributed gain light emitting devices that include a plurality of optical gain media including active emitter layers dispersed throughout a distributed feedback structure. In some examples, the distributed feedback structures enable direct electrical stimulation of each of the plurality of emitter layers and constitute a periodic array of high quality factor (high-Q) optical resonator cavities and/or a Bragg-type periodic variation in effective refractive index. In some examples, the same active emitter layer, such as the same OLED structure, is repeated throughout the periodic array such that each emitter is substantially identical. In some examples, the same active emitter layer, such as the same OLED structure, is repeated throughout the periodic array in an alternating fashion. In some examples, each of the emitter layers are electrically driven in parallel. In some examples, photonic structures disclosed herein are designed and configured to provide a desired light emission pattern, for example, by varying the periodicity of the photonic structure. In some examples, photonic structures disclosed herein are designed and configured to provide a desired light emission pattern, for example, by introducing an aperiodicity to the photonic structure. Distributed feedback distributed gain light emitting devices made in accordance with the present disclosure may be designed for a variety of applications including as an incoherent light source for use in displays, lighting, and spectroscopy, among others, and as a coherent light source in laser applications.

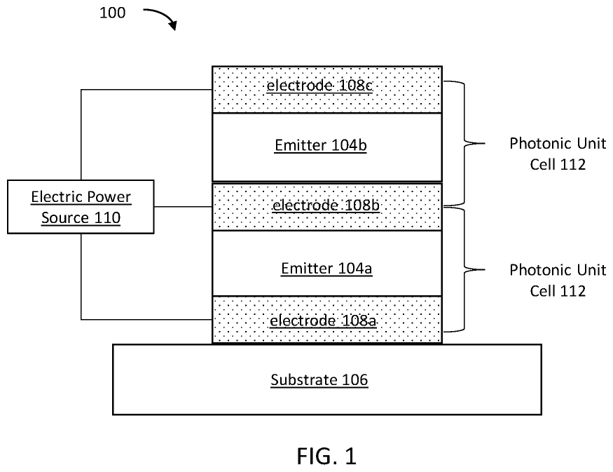

FIG. 1 shows one example of a light emitting device 100 that includes a periodic one dimensional array of emitters 104a, 104b stacked in a vertical arrangement on a substrate 106 and a plurality of electrodes 108a-108c for electrically driving, also referred to as electrically pumping, each of the emitters 104 by an electrical power source 110, each of the emitters separated by one of the electrodes and adjacent emitters sharing a common electrode. In one example, each of emitters 104 are driven in parallel by power source 110. The light emitting device 100 includes layers of materials that form a photonic structure that includes a plurality of photonic unit cells 112 in a stacked one-dimensional arrangement. The photonic structure is designed to allow or prevent light transmission according to the wavelength of light, thereby only transmitting or reflecting light of specific wavelengths. In some examples, device 100 may include layered structures of dielectric material having a refractive index that is different from a refractive index of the surrounding dielectric material. The photonic structures within device 100 may include a one dimensional photonic structure, for example, approximating a Bragg grating, and/or a two or three dimensional photonic structure, the one, two, or three dimensional photonic structure containing electrically driven light emitters 104.

In some examples, device 100 may include layered structures that define a plurality of microcavities, each photonic unit cell 112 including at least one microcavity. In the illustrated example, each photonic unit cell 112 includes only one microcavity. As described more below, in examples where there is a sufficient difference in one or more optical characteristics of one of the electrodes 108, emitters 104, or other portion of a microcavity from other electrodes, emitters, or microcavities in the device 100 that creates an asymmetry in the photonic structure, the photonic unit cell may include two or more microcavities. For example, if electrode 108b has a sufficiently different characteristic from electrodes 108a and 108c that results in the penetration depth of electrode 108b being sufficiently different than the penetration depth of electrodes 108a and 108c, the example device 100 illustrated in FIG. 1, having two microcavities, would consist of only one photonic unit cell 112. In another example, if the emitters 104a and 104b differ in structure, for instance, by containing different organic materials or material thicknesses, such that one or more optical characteristics of emitters 104a and 104b differ substantially, the example device 100 illustrated in FIG. 1, having two microcavities, would consist of only one photonic unit cell 112, wherein said unit cell is defined by a two-cavity configuration. In a further example, if the emitters 104a and 104b differ in structure, for instance, by containing different organic materials or materials thicknesses, but the overall optical characteristics of emitters 104a and 104b do not differ substantially, the example device 100 illustrated in FIG. 1, having two microcavities, would consist of two photonic unit cells 112, wherein said unit cells are defined by only one microcavity each.

In one example, one or more of electrodes 108 are opaque and reflective and other ones of electrodes 108 are reflective and semitransparent. In other examples, one or more of electrodes 108 may be transparent and device 100 may include one or more reflective or partially reflective layers (not illustrated) that define a microcavity. In one example, two reflecting electrodes 108 define a microcavity structure, where optical interference in the structure results in a resonance condition. Emission of light by emitters 104 located between reflecting electrodes 108 near the resonance wavelength is enhanced and emission away from the resonance wavelength is depressed. The optical path length (OPL) of photonic unit cells 112 of device 100 may be tuned by selecting the thickness of emitter 104, for example, the thickness of the layers that make up the emitters and/or by placing one or more transparent optical spacers between the electrodes. In the illustrated example, device 100 includes two photonic unit cells 112 in a stacked arrangement, however, in other examples, the device may include any number of photonic unit cells, for example, greater than 2 photonic unit cells, and in some examples greater than 20 photonic unit cells. In some examples, stacked arrays of microcavities, such as devices 100 and 200, made in accordance with the present disclosure contain at least two photonic unit cells because the crystalline nature of the stacked microcavity-with-emitter structure emerges when the number of unit cells is at least two. In examples where the photonic structure is highly symmetric, the at least two photonic unit cells may consist of a total of two microcavities. In examples where an asymmetry is present, the at least two photonic unit cells may consist of at least four microcavities. In some examples devices made in accordance with the present disclosure may include between 2 and 20 photonic unit cells, and in some examples, between 2 and 15 photonic unit cells, and in some examples, between 2 and 10 photonic unit cells, and in some examples, between 2 and 6 photonic unit cells may be used, and in some examples between 3 and 20 photonic unit cells, and in some examples, between 3 and 15 photonic unit cells, and in some examples, between 3 and 10 photonic unit cells, and in some examples, between 3 and 6 photonic unit cells may be used, and in some examples between 4 and 20 photonic unit cells, and in some examples, between 4 and 15 photonic unit cells, and in some examples, between 4 and 10 photonic unit cells, and in some examples, between 4 and 6 photonic unit cells may be used. In some examples, devices made in accordance with the present disclosure may include at least 3 microcavities positioned in a stacked array, and in some examples, at least 4 microcavities, and in some examples, at least 5 microcavities, and in some examples, at least 6 microcavities and in some examples, at least 7 microcavities, and in some examples, at least 8 microcavities and in some examples at least 9 microcavities, and in some examples, at least 10 microcavities. In each of the foregoing examples, one or more of the microcavities include an emitter that is electrically driven, and in some examples, all of the microcavities include an emitter that is electrically driven, and in some examples, at least a majority of the microcavities include an emitter that is directly electrically driven.

Emitters 104 may be any type of light emitting diode, including any type of thin film light emitting diode, including any light emitting diode known in the art or developed in the future. Examples of light emitting diodes include light emitting diodes that include an organic semiconductor, such as small molecule, polymer, fluorescent emitter, and/or phosphorescent emitter organic semiconductors. Examples also include light emitting diodes formed from oxides, such as zinc oxide (ZnO) and related II-oxide semiconductors, perovskites, and quantum dots. The characteristics of each emitter 104, such as material types and thicknesses may be the same or varied to achieve a desired characteristic, such as to control the OPL of each microcavity or photonic unit cell 112 of the photonic structure to produce a desired photonic band structure and light emitting characteristics. Electrodes 108 may have a variety of characteristics depending on a particular implementation and may be transparent, or in some implementations partially transparent and partially reflective as described more herein.

In some examples, substrate 106 is designed and configured for high planarity and may be formed from one or more of a number of materials such as, for example, silicon, silicon dioxide, sapphire, or quartz. In some examples, substrate 106 additionally functions as a heat sink and has a high thermal conductivity to maximize achievable current densities. For example, substrate 106 may be only silicon or silicon with a relatively thin (e.g., <100 nm) silicon oxide coating for electrical insulation, or a polished bulk metal with patterned insulating pads to prevent shorting of the electrodes. In some examples, device 100 is encapsulated in a coating, such as an epoxy or polyurethane, as is commonly done in the art to protect organic devices from oxygen degradation, which is chosen to have high thermal conductivity and transparency.

Device 100 may also include one or more treatments (not illustrated) known in the art to reduce the amount of internal reflections in the device, loss at the emitter, or losses at the air interface to thereby improve light extraction efficiency. Non-limiting examples of treatments include one or more layers of material deposited or located on top of the device 100 to ease the transition into air such as one or more of a microlens, index matching layers, outcoupling layers, and encapsulation layers. Encapsulation also protects the device from contaminants such as oxygen and water vapor.

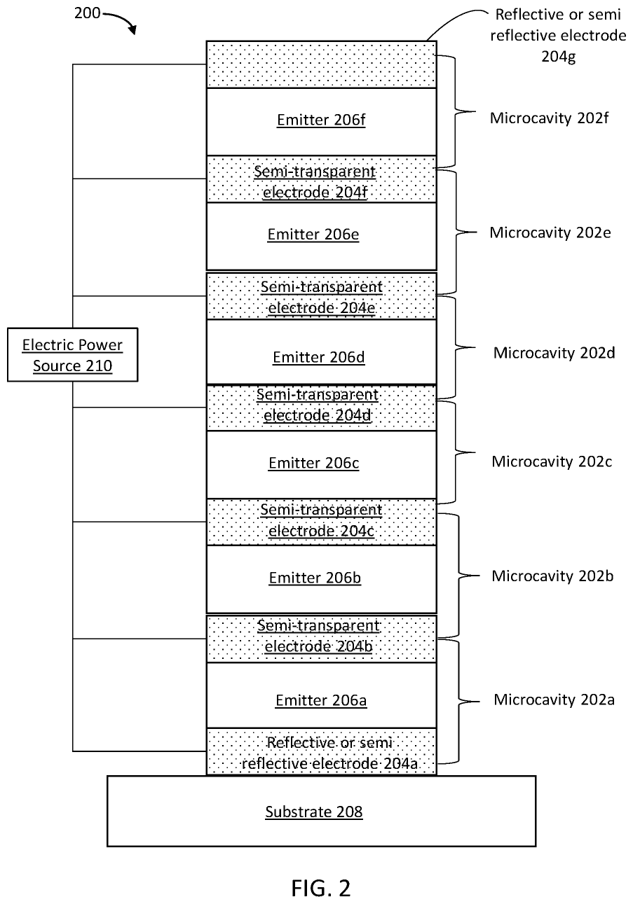

FIG. 2 shows an example light emitting device 200 that is an example implementation of lighting device 100 and includes a periodic one dimensional array of microcavities 202a-202f formed by electrodes 204a-204g separated by emitters 206a-206f, with adjacent emitters sharing a common electrode. The emitters 206 and electrodes 204 are stacked in a vertical arrangement on a substrate 208, for example a high thermal conductivity substrate such as silicon, with each of the emitters 206 independently electrically driven by an electrical power source 210. In the illustrated example, electrode 204a is a substantially opaque and reflective mirror, electrodes 204b-204f distributed across the interior of the photonic structure are semitransparent mirrors, and electrode 204g is a reflective mirror and may be either semitransparent or opaque. In some examples, each of electrodes 204 may be metallic and selected from Al, Au, Ag, Mg, Ca, or alloys thereof. Each of internal electrodes 204b-204g may be a metallic film with a thickness selected to be less than a penetration depth of light into the metal layer, or less than twice the penetration depth of light into the metal layer, in order for the electrode to be semitransparent. In one example, the penetration depth is a distance for the intensity of light traveling through the electrode to drop off to 1/e (approximately 37%). Example penetration depths for light having a wavelength of 500 nm are 40 nm for silver and 27 nm for aluminum. Thus, by way of example, each of electrodes 204b-204g may be formed from silver or silver alloy and have a thickness less than or equal to approximately 80 nm and in some examples, less than or equal to 40 nm and/or be formed from aluminum or an aluminum alloy and have a thickness less than or equal to approximately 54 nm, and in some examples less than or equal to approximately 27 nm.

In the example illustrated in FIG. 2, each emitter 206 is located in the center of the corresponding microcavity 202. The position of the emitter layer 206 in the microcavity 202 affects the outcoupling efficiency, spectral shape and peak wavelength. High symmetry, where the emitters 206 are in the center of the cavity 202, is advantageous for total light emission through the Purcell effect; this results in higher waveguiding and a shift in the emission intensity to higher angle. In other examples, one of more of the emitters 206 may be offset in the corresponding cavity 202. Offset emitters 206 result in greater normal emission but slightly lower outcoupling efficiency and Purcell enhancement. Offset emitters 206 may also affect the resonant electric field profile and thereby influence the coupling efficiency of the offset emitter 206 with one or more of the resonant modes.

Devices 100 or 200 may be modified in a number of ways. For example, one or more of emitters 206 may be replaced by a gain cavity composed purely of a gain material such as a cavity composed of pure or doped Alq3 or other laser gain material. In another example, device 200 may include one or more a thermal dissipation/buffer layers in the form of a cavity composed of TCO or transparent organics/polymers with relatively high thermal conductivity or heat capacity. This may be particularly useful for a laser in pulsed operation to absorb the heat generated in each pulse. In some examples, device 200 may include a passivation/encapsulation layer to block oxygen and water vapor, etc.

In yet other examples, device 200 may include a wetting layer to enable extremely thin (<10 nm) metal layers. For example, a cavity may be composed of TCO or some other transparent material, or a combination of a bulk transparent material with a thin film that promotes wetting of the metal mirrors on the surface. The minimum thickness of the metal layers is determined by the percolation threshold—the threshold between island formation and a continuous film. A wetting layer reduces the percolation threshold by reducing the surface energy of the interface with the metal to promote formation of the metal-wetting layer interface over the metal-vacuum interface.

As another example device 200 may be modified to include an optically active layer, such as integrated non-linear optics such as Kerr electro-optic effect for mode-locking, a Q-switching layer, or a saturable absorber. For example, one or more of cavities 202 may contain a saturable absorber, such as a thin layer of carbon nanotubes, Alq3 or laser crystals, either on its own or in addition to other materials. Examples of nonlinear materials for the Kerr effect include fused silica, perovskites, metal-organic frameworks, and other organic and inorganic materials.

In another example device 200 may include a scattering layer (e.g. nanoparticles suspended in a matrix to reduce waveguiding/enhance outcoupling), or an absorbing layer (e.g. absorbent material to suppress competing modes), for example, a layer containing a material that absorbs red light to suppress lower energy modes and enhance blue light emission, or vice-versa.

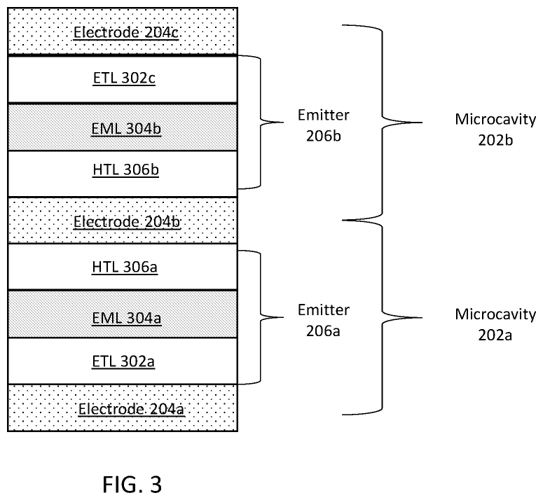

FIG. 3 provides a detail illustration of one example implementation of two of the six emitters 206 (FIG. 2) in an example where the emitters are organic light emitting diodes. As shown, in the illustrated example, each emitter 206 includes a standard OLED construction as is known in the art, and may include at least an electron transport layer (ETL) 302, an emissive layer (E-L) 304, and a hole transport layer (HTL) 306. Electrodes 204a and 204c adjacent ETLs 302 are cathodes and electrode 204b adjacent HTLs 306 is an anode. In one example, the remaining emitters 206 of device 200 may be the same as emitters 206a and 206b shown in FIG. 3, while in other examples, they may be different. Each of electrodes 204 may have the same construction or may vary. In one example, each of the cathodes (electrode 204a, 204c, etc.) may be formed from a first material, for example, silver or an alloy thereof, such as an Ag:Al alloy, and may also be coated with a coating material such as Molybdenum Oxide (MoOx), which acts as a hole injection layer (HIL) for improved electronic efficiency, as is commonly done in the art. Each of the anodes (e.g. electrodes 204b, 204d, etc.) may be formed from a second material, for example, aluminum or an alloy thereof, such as an Ag:Al or Ag:Mg alloy, and coated with a coating material, such as LiF, which acts as an electron injection layer (EIL). In another example, an Ag:Al (15:1) alloy may be used for the anode and an Ag:Mg (10:1) alloy for the cathode. In other examples, an Ag:Mg alloy, for instance a 10% Mg-90% Ag alloy, or a 5% Mg-95% Ag alloy, may be used for the cathode, which may reduce the work function of the metal to enhance charge injection efficiency at the cathode, increase the thermal stability and decrease the surface roughness as compared to pure Ag films. The similar optical properties of Ag, Ag:Al alloy and Ag:Mg alloy may enable highly symmetric photonic unit cells when used for each of electrodes 204.

As described more below, when the anode and cathode materials and/or thickness are appreciably different, a Peierls distortion is created which effects the photonic energy bands of the device. Using differing materials for the anode and cathode also changes the number of microcavities that make up a single photonic unit cell. If, for example, the cathodes (electrode 204a, 204c, etc.) are formed from pure Al and or another first material and the anodes (e.g. electrodes 204b, 204d, etc.) are formed from pure Ag, Ag:Al alloy or some other second material that has sufficiently different optical properties from the first material that results in a breaking of the symmetry of the photonic crystal, the result is a doubling of the length of the photonic unit cell which correspondingly impacts the OPL of the device. As a another example, the similar optical properties of Ag, Ag:Al alloy and Ag:Mg alloy may enable highly symmetric photonic unit cells when used for each of electrodes 204, for instance, by using Ag:Mg alloy as the cathode material and pure Ag or Ag:Al alloy as the anode material, such that each photonic unit cell consists of a single microcavity.

Much of the difference in optical behavior between the use of a first and second material as the electrode can be captured by the penetration depth p, of the material given by the following equation:

$$\\ \begin{matrix}ϕ = arc tan ( \frac{{n}_{org} {k}_{m}}{{n}_{org}^{2} - {n}_{m}^{2} - {k}_{m}^{2}} ) & Eqn . ( 2 )\end{matrix}$$

where n_{org} is the index of refraction of the adjacent organic layer and nm and km are the real and imaginary parts of the index of refraction of the metal. Using this equation, the penetration depth of silver at 550 nm (40 nm) is substantially larger than that of aluminum (27 nm) and hence more silver is required to achieve an equivalent absorption. This is offset by the lower real index of refraction for Ag (0.06) compared to Al (0.79), which affects the optical pathlength through the mirrors. The combination of these effects result in the silver and aluminum mirrors playing different roles within the device structure.

Each of ETL 302, EML 304, and HTL 306 may be formed from any material known in the art of OLEDs. Each cathode, anode, EIL and HIL may be formed from any material known in the art. By way of non-limiting example ETL 302 may be NBPhen, EML 304 may be AlQ3, and HTL 306 may be NPB. Selection of OLED materials (e.g., one of more of electrodes 204, ETL, EML, and HTL) may meet the ordinary criteria for electronic and emission efficiency, as well as the additional criterion of high planarity, as required for multiple layers of high-Q resonators. In one example, OLED materials are chosen to have a root-mean-square (RMS) surface roughness of less than 10 nm. In one example, OLED materials are chosen to have a root-mean-square (RMS) surface roughness of less than 5 nm. In another example, OLED materials are chosen to have a root-mean-square (RMS) surface roughness of less than 1 nm.

As will be appreciated by persons having ordinary skill in the art, the foregoing example OLED construction is a simplified example for ease of illustration and provided by way of example, however, more advanced and complicated OLED designs known in the art may be utilized as needed for a particular application. For example, any of the OLED constructions described in Salehi, A., Fu, X., Shin, D. H., and So, F., “Recent Advances in OLED Optical Design,” Advanced Functional Materials 29, no. 15 (2019): 1808803-21. doi:10.1002/adfm.201808803; Geffroy, B., le Roy, P., and Prat, C., “Organic Light-Emitting Diode (OLED) Technology: Materials, Devices and Display Technologies,” Polymer International 55, no. 6 (2006): 572-582. doi:10.1002/pi.1974; Islam, A., Rabbani, M., Bappy, M. H., Miah, M. A. R., and Sakib, N., “A Review on Fabrication Process of Organic Light Emitting Diodes,” (2013): 1-5. doi:10.1109/ICIEV.2013.6572656; Thejo Kalyani, N. and Dhoble, S. J., “Organic Light Emitting Diodes: Energy Saving Lighting Technology—a Review,” Renewable & Sustainable Energy Reviews 16, no. 5 (2012): 2696-2723. doi:10.1016/j.rser.2012.02.021; or Shinar, J. and Shinar, R., “Organic Light-Emitting Devices (OLEDs) and OLED-Based Chemical and Biological Sensors: an Overview,” Journal Of Physics D-Applied Physics 41, no. 13 (2008): 133001. doi:10.1088/0022-3727/41/13/133001 may be used, each of which are incorporated by reference herein in their entireties.

In the illustrated example, light emitting device 200 has a simple construction that is easy to manufacture, particularly at scale, due to the low energy processing which does not require lithography or heat treatments and allows the possibility of roll-to-roll or large area processing. The nanometer scale electrode mirrors 204 (having a thickness in some examples on the order of 10 nm-30 nm) have a thickness that is below the percolation threshold for pure silver, and minimizing a surface roughness of the layers of the device, such as the electrodes, maximizes optical efficiency. In one example, the anodes are formed from a 95% silver-5% aluminum alloy to reduce the silver percolation threshold to enable the formation of smooth nanometer scale electrodes. In one example, the cathodes are formed from a 90% silver-10% magnesium alloy to reduce the silver percolation threshold to enable the formation of smooth nanometer scale electrodes with reduced work function.

By disposing each emitter 206 between reflective electrodes 204, a plurality of microcavities 202 are formed that are designed and configured to each create a microcavity effect to thereby control the electrically-driven emission from the emitters. By providing one or more semitransparent electrodes 204 between adjacent microcavities 202, the semi-transparency allows interaction of the resonant modes of the adjacent microcavities 202 and results in the formation of a photonic energy band structure that has characteristics associated with the periodicity of the overall device structure. As will be described in detail below, without being bound by theory, the photonic energy band structure is formed by the perturbation of the photonic energy states that would be present in a single extended microcavity of equivalent optical pathlength as the overall device 200 but with internal electrodes 204b-204f removed. The addition of internal electrodes 204 raises the energy of the microcavity states of equation 1 of the extended microcavity in inverse proportion to the number of node-mirror overlaps. That is, the λ/2 mode of equation 1, having nodes only at the outer-most mirrors, experiences the greatest perturbation and increase in energy, while modes with a greater number of node-mirror overlaps experience lower perturbation. As noted above, in other examples, one or more of electrodes may be transparent and an additional layer of reflective semitransparent material may be included to create the microcavity effect.

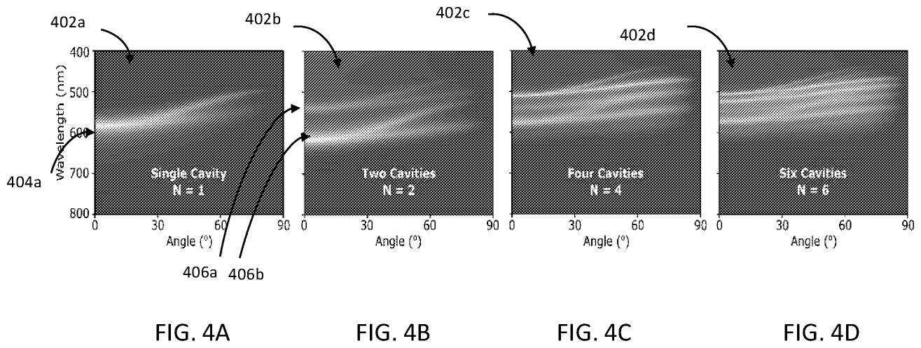

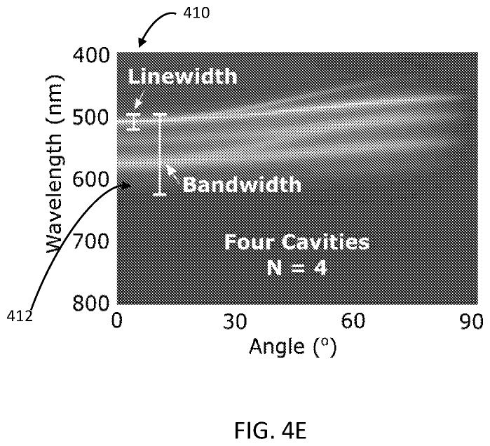

The interaction between microcavities 202 gives rise to a new set of resonant modes corresponding to the larger periodic structure, where the total number of resonant modes equals the number of microcavities 202. The resonant modes of the photonic crystal form a photonic energy band, as shown in FIGS. 4A-4E, where the band is made up of allowed energy levels of the structure. In the illustrated example, each resonant mode of a single microcavity 202 splits into N separate states when put in contact with N−1 other microcavities. FIGS. 4A-4E illustrate example photonic energy bands 402 for photonic structures with 1, 2, 4, and 6 microcavities 202, respectively, in each case, each microcavity has a fundamental λ/2 mode located at about the same energy. As illustrated, comparing FIGS. 4A and 4B, as the number of microcavities 202 increases from 1 to 2, the photonic energy band 402 goes from 1 state 404a to two states 406a, 406b. When the number of microcavities 202 increases from 2 to 4, the photonic energy band 402 goes from two states to four states, and so on. FIG. 4E illustrates the concepts of full-width-at-half-max (FWHM), or linewidth 410 and the bandwidth 412 of the photonic energy band for a four microcavity photonic structure. Comparing FIGS. 4A-4D, as more microcavities 202 and hence more states are added, the linewidth 410 of each state decreases, while the bandwidth 412 increases. As will be described in more detail below, both of these effects experience a tapering as the number of cavities increases, with diminishing gains at large N.

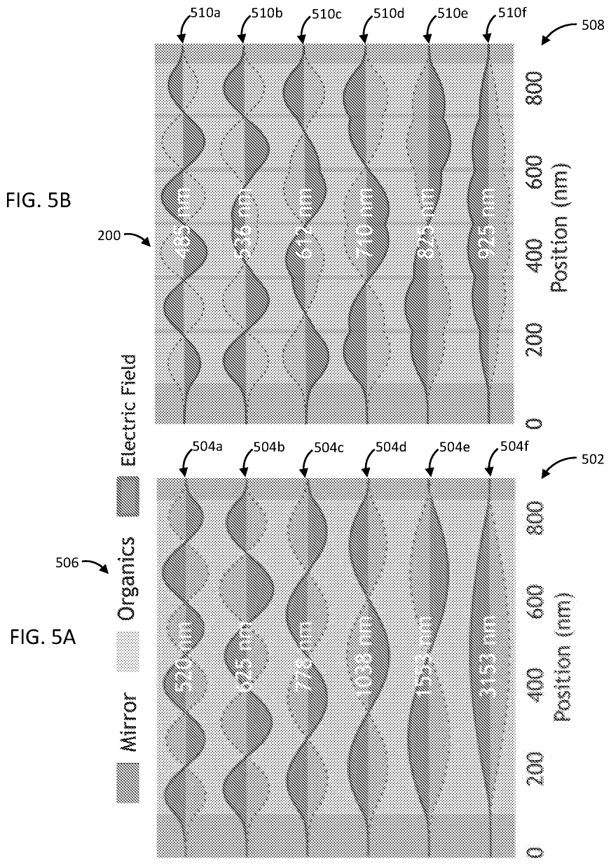

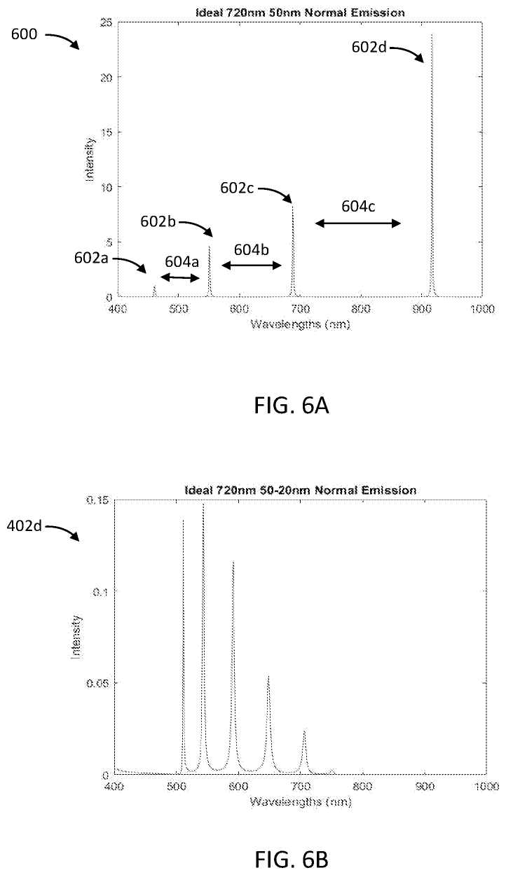

FIG. 5A illustrates the electric field profile 502 of the resonant modes 504a-504f within a large 3λ microcavity 506 that is equivalent to light emitting device 200 without the internal mirrors formed by electrodes 204. FIG. 5B illustrates the electric field profile 508 of the resonant modes 510a-510f within the six λ/2 cavity device 200 (see also FIG. 2) that includes internal mirrors formed by electrodes 204b-204f wherein each cavity has a λ/2 mode located in the visible range. Each of the states 404 in a photonic energy band 402 (see FIG. 4D) corresponds to a resonant electric field mode 510. Comparing FIGS. 5A and 5B, it is apparent the electric field profile 508 of the six cavity device (FIG. 5B) has a similar spatial distribution to the electric field profile 502 of the single large microcavity (FIG. 5A), however, as shown in FIGS. 6A and 6B, the energy profile is quite different. FIG. 6A illustrates the photonic band structure 600 for a large microcavity having a 3) OPL and FIG. 6B illustrates the photonic band structure 402d for six λ/2 cavity device 200 (see also FIG. 2 for a schematic of device 200 and FIG. 4D for another illustration of the photonic band structure). As shown in FIG. 6B, semitransparent electrodes 204 inside of the outer microcavity 202f act as perturbations and bring the 3λ cavity modes 504 and 602 together in energy, substantially centered on the single-cavity λ/2 mode, in the illustrated example, at 550 nm. By contrast, as shown in FIG. 6A, in the absence of the internal electrodes 204 and with only bottom electrode 204a and top-most electrode 204g each of the states 602a-602d are separated by a large energy gap 604a-604c. FIG. 6B shows how the presence of the internal electrodes 204b-204f dramatically reduces the energy separation of the states. The reduction in energy separation may be due to the energy cost of passing through the electrodes 204b-204f, which is in proportion to the number of node-overlaps in the spatial distribution of the resonant photonic states. For this reason, the energy of the bottom-most fundamental λ/2 mode of the 3) cavity, with only two node overlaps (one each at the top-most and bottom-most mirrors), is increased greatly whereas the highest order, 3λ, energy mode, with seven node-overlaps (one at each internal mirror and the top-most mirror) is only slightly increased, resulting in the band compression shown in FIG. 6B. Thus, the photonic structure of light emitting device 200 combines the high electronic efficiency of a small OPL microcavity, for example, a fundamental λ/2 mode single microcavity, with the optical properties typically associated with a higher order mode of a larger OPL microcavity. Such a device possesses greatly reduced linewidth in the emission peaks as compared to a single microcavity emitter. For instance, a multi-microcavity device may have a linewidth of less than 1 nanometer, compared to a linewidth of 20 nm for a typical single microcavity. Such a multi-microcavity device also possesses a larger bandwidth than a single microcavity emitter, the band comprising the additional photonic energy states created by the interaction of multiple microcavities. For example, a light emitting device such as device 200 or 1000 may be designed and configured to emit a large bandwidth of light, for example, white light emission.

FIGS. 4A-6B illustrate the angle-resolved emission of the photonic energy bands for an ideal case where photonic structures such as device 200 are perfectly periodic and wherein each photonic unit cell comprises a single cavity. Imperfections in the structure and deviations from a fully periodic one-dimensional structure comprising single-cavity photonic unit cells, including either non-periodic or periodic aperiodicities, cause deviations from the ideal case. A non-periodic aperiodicity occurs, for instance, only once in the photonic structure and does not affect the definition of the photonic unit cell. A non-periodic aperiodicity may influence the resonant energies of the photonic structure by modulating the extended cavity states as discussed above in FIG. 5A and FIG. 5B but does not affect the states of the individual unit cells. By contrast, a periodic aperiodicity, such as a Peierls distortion, is repeated regularly throughout the structure. A periodic aperiodicity changes the definition of the photonic unit cell so that multiple cavities are required to form the repeat unit. As an illustrative example, forming a photonic structure according to the methods of this disclosure utilizing only Ag mirrors and identical microcavities would result in an ideal photonic structure with a photonic unit cell that comprises a single microcavity bounded by Ag mirrors. Alternatively, forming a photonic structure according to the methods of this disclosure utilizing alternating Ag and Al mirrors would result in a photonic structure described by a photonic unit cell that comprises two microcavities, wherein the unit cell is bounded by either Ag or Al mirrors, and the two cavities inside of the cell are separated by the second mirror material. This two-cavity unit cell is an example of the Peierls distortion, a periodic aperiodicity. In a further example, a set of three or more mirrors may be used as a repeat unit, for instance, a photonic structure may be formed by the sequence Ag, Al and Mg in a repeating fashion so that the photonic structure is defined by a three-cavity photonic unit cell. In another example, the periodic aperiodicity may consist of a sequence of thicknesses or composition of the mirrors or the cavities, such that a photonic structure comprising a repeating sequence of cavity thickness of, for instance, 100 nm, 120 nm and 130 nm, separated by substantially identical mirrors, may be described by a three-cavity photonic unit cell.

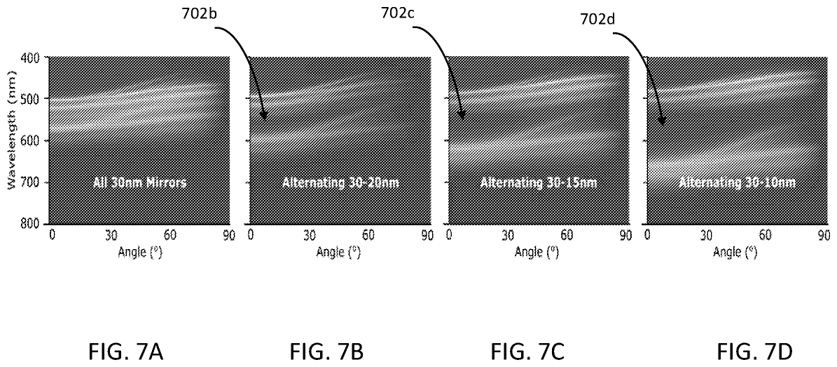

The periodicity of a photonic structure such as device 200 defines the photonic energy band structure of the device. A perfect photonic structure comprising single-cavity photonic unit cells exhibits substantially evenly spaced resonant energy states, reflecting the evenly spaced energy levels of the single cavities as described by Equation 1. When a defect is introduced to the crystal structure, the periodicity is disrupted and can result in a band gap that divides the energy band into two separate bands of slightly higher or lower energy than the perfect crystal. An example of such an effect is illustrated in FIGS. 7A-7D which illustrate photonic energy bands for example implementations of device 200 in the form of a six microcavity one-dimensional photonic structure with varying electrode thicknesses. FIG. 7A illustrates the photonic energy band for a perfectly periodic structure having equal thickness electrodes 204. FIGS. 7B-7D illustrate the effect of the introduction of a periodic defect in the form of a reduction in the thickness of every other electrode, e.g., a reduction in the thickness of electrodes 204b, 204d, and 204f, where the defect results in a bandgap 702b-702d. The defect results in a change in the definition of the photonic unit cell such that the cell comprises two cavities and therefore the energy band of the perfect crystal of FIG. 7A splits into two sub-bands. Similarly, a three-cavity unit cell may result in the formation three sub-bands. As the defect in the periodicity is increased by further reduction in the electrode thickness, the size of the perturbation in the form of band gap 702 increases. Instead of or in addition to changing the thickness of the electrodes, a distortion can be introduced by changing the thickness of one or more of microcavities 202, or changing the optical properties of one or more electrode/mirror 204 or emitter 206.

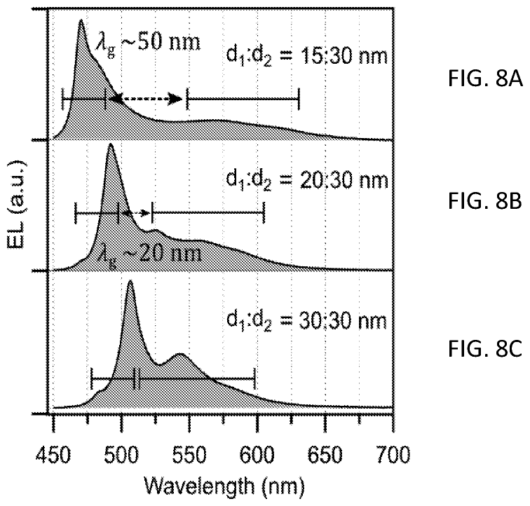

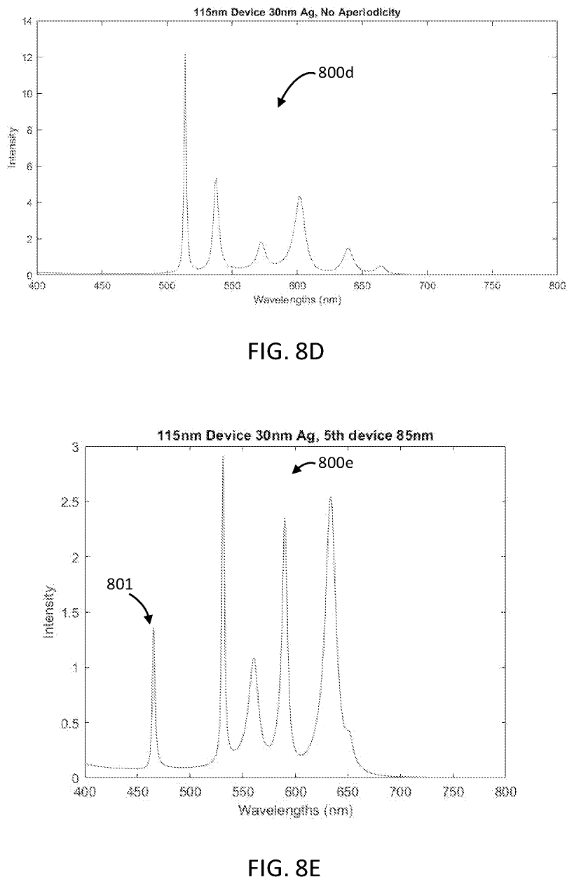

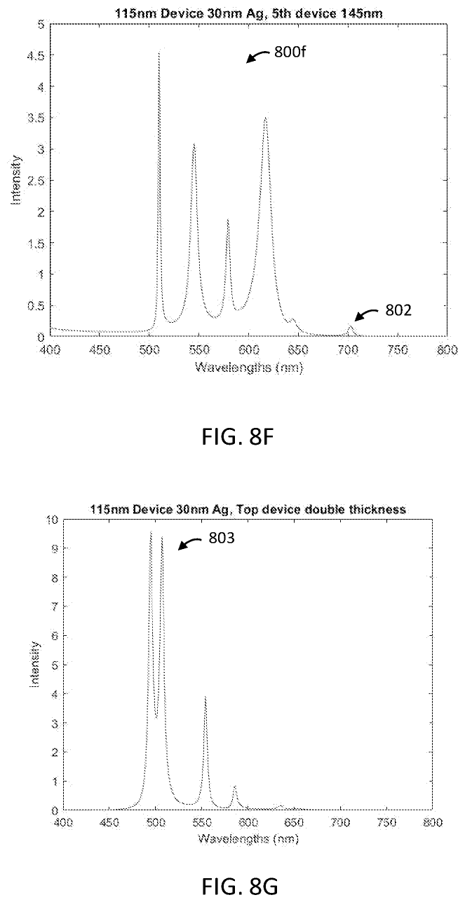

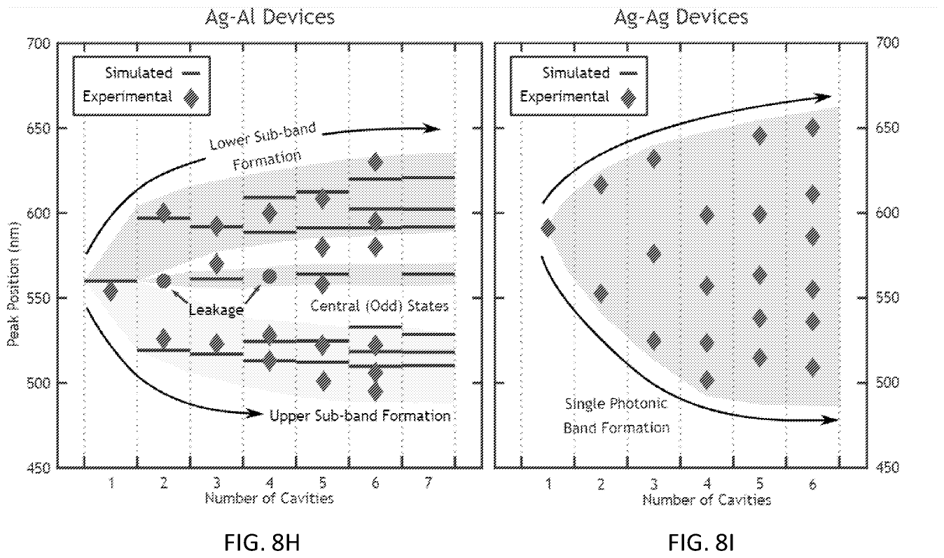

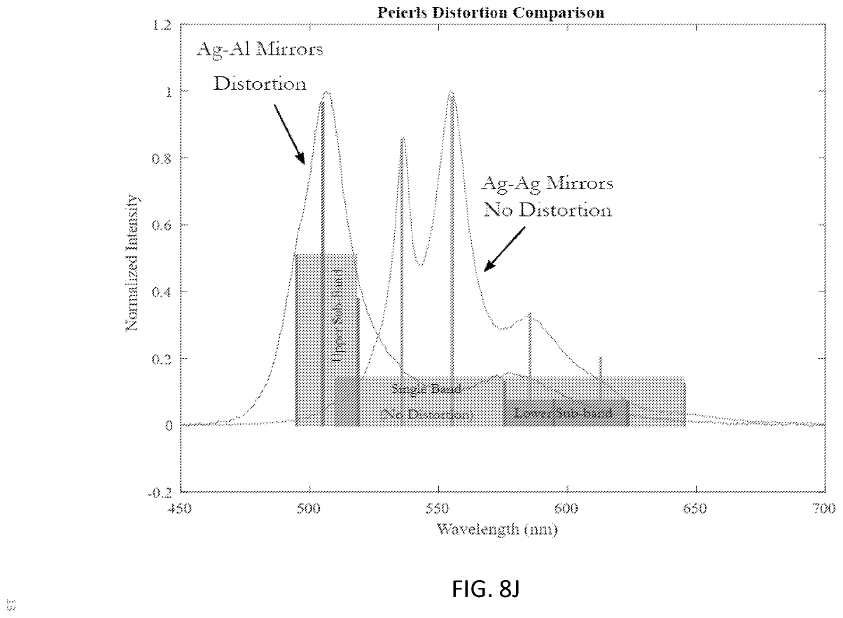

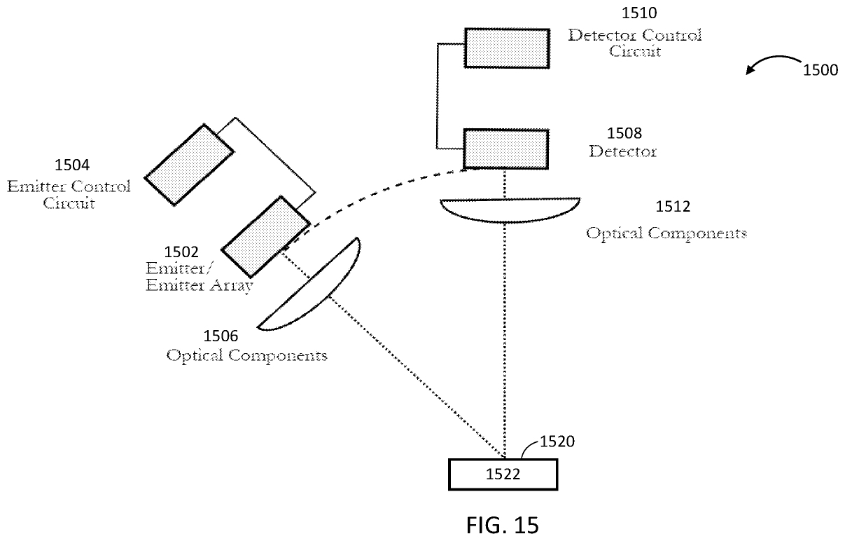

FIGS. 8A-8C illustrate experimental data from another example of a perturbation caused by introducing two periodic defects or variations from a periodic structure, namely, using a different material for the cathode (for example, Ag/MoOx) and anode (e.g., Al/LiF) electrodes 204 and varying the thickness of the cathodes from being the same as the anodes (FIG. 8C, each electrode having a 30 nm thickness), reducing to 20 nm (FIG. 8B) and 15 nm (FIG. 8A). As the cathode mirror thicknesses are decreased, the existing band gap is enhanced. Despite the anode and cathode mirrors being equal thickness in FIG. 8C, a small band gap is present due to the material differences between Ag/MoOx and Al/LiF, representing a periodic defect. As also shown in FIGS. 8A-8C, by reducing the thickness of the cathode, the distribution of light from the photonic structure is affected. More generally, the introduction of a defect to the periodic structure of the device, such as device 200, provides a high degree of control over the light emitted from the device and enables the suppression or enhancement of specific light energies. For example, increasing a size of a bandgap through the introduction of a defect in the otherwise periodic photonic structure, allows separation of the states of the device so that only a reduced number of states overlap the electroluminescence spectrum of the emitter 206 and other unwanted states do not such that a resonance and emission of light at the unwanted states does not occur.

By way of non-limiting example of a non-periodic aperiodicity, a characteristic of only one microcavity, such as a top-most microcavity, e.g., microcavity 202f may be varied so that the microcavity resonates at a different energy than the other microcavities 202 in device 200. In one example, a perturbation may be introduced to the top-most cavity 202f because the perturbation in the top-most cavity would outcouple more efficiently than other ones of cavities 202a-202e due to the lack of screening by additional microcavities. Outcoupling refers to the strength of the emission seen on the outside of the device. Outcoupling efficiency is the ratio of the light intensity seen on the outside to the intensity of light that is actually emitted on the inside of the device. In other examples, a defect or aperiodicity in the periodic photonic structure may be introduced in any of cavities 202 to cause a similar effect. The position of the defect in the periodic structure affects the amount of perturbation in the photonic energy band and which states it would affect (eg. even vs. odd states).

FIGS. 8D-8G illustrate results from transfer matrix simulations of example six-microcavity devices with varying aperiodic characteristics. FIG. 8D demonstrates the emission spectrum of a baseline device, which consists of a periodic structure of six microcavities where each microcavity has a total thickness of 115 nm, designed to operate at the λ/2 mode with 30 nm silver mirrors. The six photonic states within photonic band 800d correspond to the peaks of FIG. 8D and are nearly evenly spaced in energy due to the high degree of periodicity in the photonic crystal. The use of exclusively silver electrodes in the simulation removes the Peierls distortion due to the differing electrode materials as discussed herein in reference to FIGS. 7A-7D. FIG. 8E shows the emission spectrum of the same device as FIG. 8D, where an aperiodicity has been introduced by reducing the thickness of the fifth microcavity (the second from the top) to 85 nm. FIG. 8E demonstrates the separation of the highest-energy state 801 from the photonic band 800e. This demonstrates the ability to precisely place a single peak at a higher energy through the introduction of a thickness perturbation within the crystal.

Similarly, FIG. 8F shows the emission spectrum of the same device as FIG. 8D, with the introduction of an aperiodicity by increasing the thickness of the fifth microcavity to 145 nm. As can be seen, lowest energy state 802 has been separated from the rest of the photonic energy band 800f, bringing it lower in energy, while slightly perturbing the states within photonic energy band 800f relative to the corresponding states in band 800d. FIG. 8G shows the effect of changing the thickness of the top-most cavity of the device simulated in FIG. 8D to 230 nm, or twice the original thickness, thereby corresponding to a λ mode cavity. This results in the separation of two states 803 due to the two modes within a λ cavity (λ/2 and λ). For the sake of brevity, additional simulations have been omitted which demonstrate that fine control of the thickness of a mixed-order cavity allows tuning of the emission spectrum to provide a variety of effects, including separation of the lowest-energy states, reduction in the FWHM of one or more peaks due to the higher-order device, and the introduction of one or more band-gaps. It will be appreciated by those skilled in the art that a near-infinite number of variations on the core design are possible, and the examples included herein are meant as a non-limiting demonstration of the flexibility of the core design. Depending on the application, a base crystal and set of defects may be designed to achieve a desired photonic band structure using the methods described herein.

FIGS. 8H-8J further illustrate the effect of the characteristics of the electrodes and more generally the impact of aperiodicity of the photonic structure on optical performance. FIG. 8H shows computationally simulated and experimentally resolved peak positions of the states of the photonic energy band for devices with 1 through 6 microcavities, each being an instantiation of example microcavities 202 (FIG. 2) for a device with 15:1 Ag:Al alloy/MoOx as the anode and Al/LiF as the cathode (referred to by shorthand in FIG. 8F as an Ag/Al device). As shown in FIG. 8H, the states separate into two sub-bands (labeled as upper and lower sub-band in FIG. 8F) with a bandgap in between.

FIG. 8I shows computationally simulated and experimentally resolved peak positions of the states of the photonic energy band for devices with 1 through 6 microcavities for a device an Ag:Al (15:1) alloy for the anode and Ag:Mg (10:1) alloy for the cathode, referred to by shorthand as an Ag/Ag device. The resulting higher symmetry in the crystal structure due to the optical properties of the material of the anode and cathode being more similar as compared to the Ag/Al device of FIG. 8H eliminates the band gap and enables the formation of a single energy band rather than two sub bands. The greater symmetry also results in a greater resolution of the peaks of each state.

FIG. 8J shows the normalized intensity 820 of the emission of the six cavity Ag/Al device from FIG. 8H and the normalized intensity 822 of the emission of the six cavity Ag/Ag device from FIG. 8I. As with FIG. 8H, FIG. 8J similarly shows the band gap 824 between the states of the Ag/Al device and the more uniform distribution of the states in the Ag/Ag device.

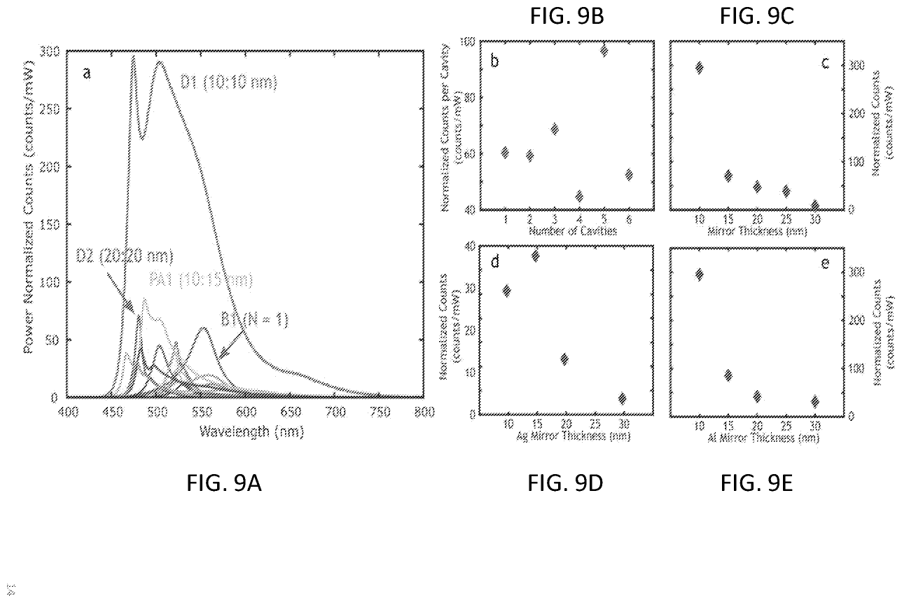

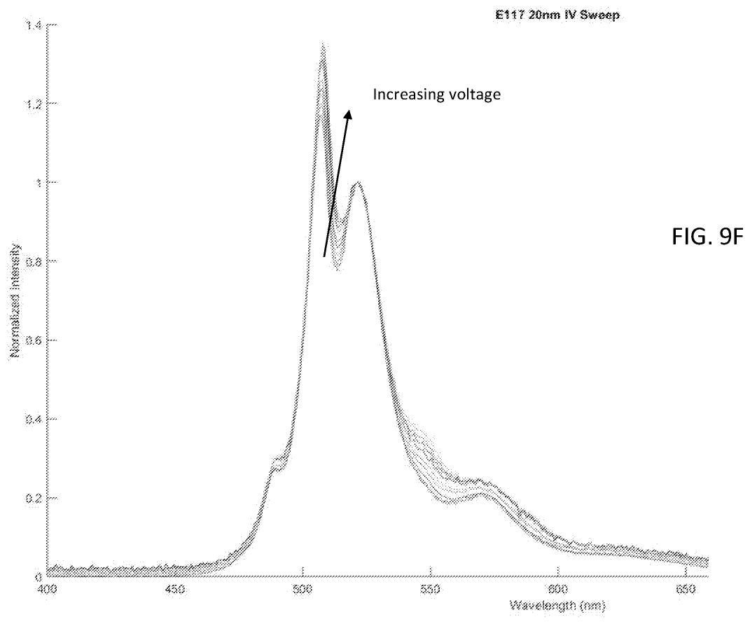

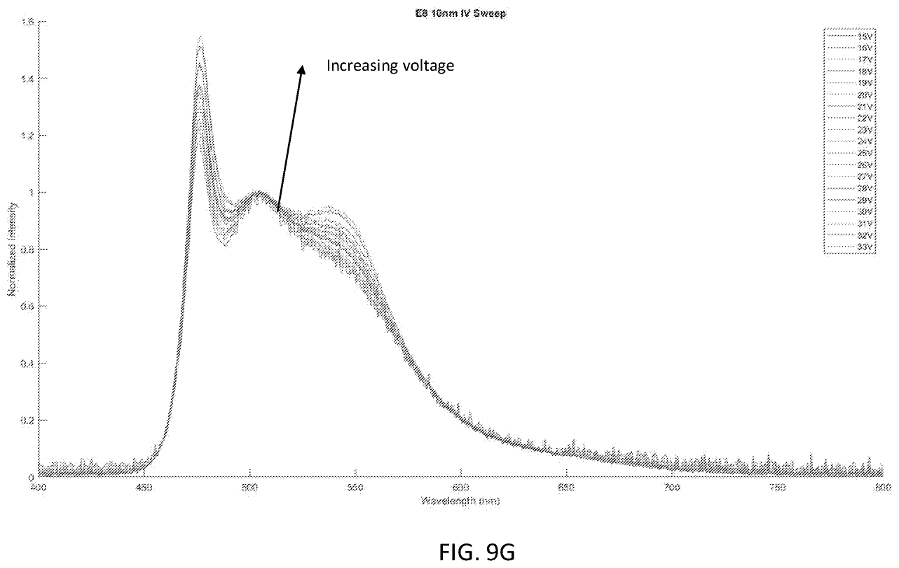

FIGS. 9A-9E illustrate relative emission intensity of stacked microcavity devices according to the number of cavities, mirror thickness, and mirror composition. FIG. 9A shows the emission spectra in terms of normalized counts, where counts are the raw data supplied by a spectrometer and normalization is accomplished by dividing by the power put into each device. The data in FIG. 9A provides a comparative measure of emission efficiency of the devices tested. FIGS. 9B-9E similarly illustrate relative emission efficiency and show the trend in the maximum peak height in the power normalized data as a function of mirror thickness and number of cavities. As can be seen in FIGS. 9C-9D, the emission efficiency increases dramatically as the mirror thickness is reduced. A second trend shown in FIG. 9B is that the emission efficiency may be higher for devices with an odd numbers of cavities. The devices used to generate the data in FIG. 9 were an instantiation of devices 100 and 200 and had a Ag/Al electrode construction, resulting in two microcavities 202 forming a single photonic unit cell 112. The increased emission efficiency of the devices with an odd number of cavities may be due to having a silver mirror on top of the device or due to the crystal structure itself due to the splitting of one of the two microcavity photonic unit cells.

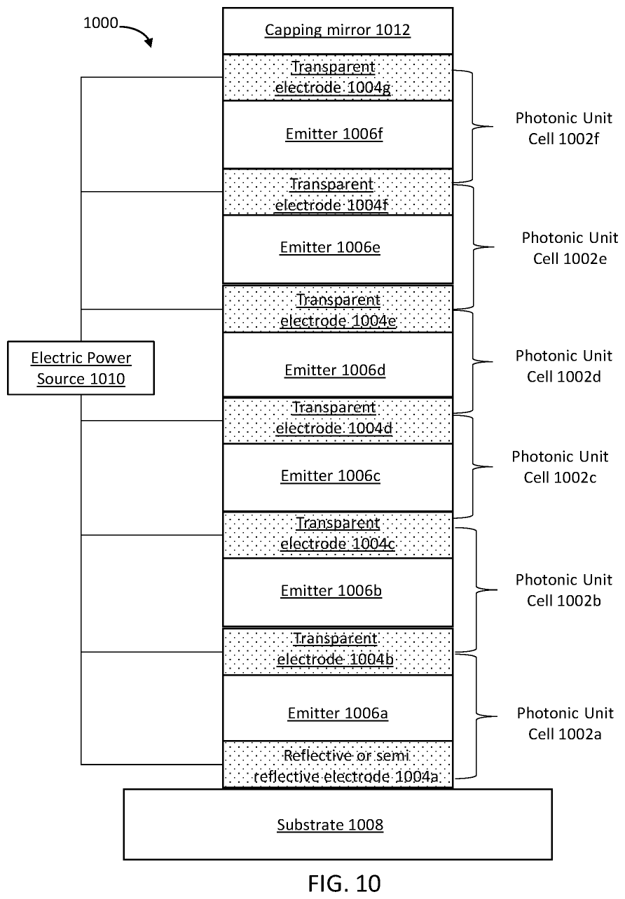

The characteristics of light emitted from device 200 may also be controlled by controlling a driving current supplied by, e.g., electrical power source 210, to each of emitters 206. For example, a driving current may be selected, designed, and configured to maximize a power output in a particular resonance mode of one or more of microcavities 202. The power distribution across the resonance modes of each microcavity 202 varies with driving current. Without being limited to a particular theory, this is understood to be due to the coupling of the excitonic energy modes of the emitters 206 to the resonance modes of the microcavities 202, the effects of stimulated emission and the Purcell effect, where excitonic energy modes refers to the electrically-generated molecular dipoles whose collapse produces the light emission. Thus, in one example, a mode redistribution is controlled through control of driving current. In some examples, there is a non-linearity of the power dependence in the stimulated emission regime of the emitters 206 that results in the output power of the microcavities 202 in certain modes increasing much faster than others with an increase or decrease in driving current. An example of the impact of driving current on mode redistribution is illustrated in FIGS. 9F and 9G which shows experimental results in an example implementation of device 200 that included a six-microcavity OLED stack with 20 nm equal-thickness electrode mirrors (FIG. 9F) and 10 nm equal-thickness electrode mirrors (FIG. 9G). As shown, as the voltage was increased (in the example from 15V to 34V), the emission shifted into the highest energy mode. Emission is normalized to the peak located at ˜503 nm to demonstrate the increase in emission from the highest energy peak relative to the other peaks. The overall emitted intensity increases with higher current, and the observed redistribution of emission among the modes is stable and reversible by reduction of current.

Without being bound by theory, this is believed to be the result of sub-threshold stimulated emission, or charge-injection modulation by the standing-wave electric field in the device. FIGS. 9F and 9G illustrate sub-threshold stimulated emission because the rate of stimulation depends on the level of loss. Increased optical loss reduces all peaks evenly for purely spontaneous emission, while for stimulated emission it only reduces those peaks that are being stimulated. This means that the observed change in emission in FIGS. 9F and 9G is not due to spontaneous emission or amplified spontaneous emission (ASE), since these phenomena would affect all peaks equally, whereas FIGS. 9F and 9G show only a decrease in the stimulated peaks. In one example, sub-threshold stimulated emission is selectively controlled to cause a light emitting device such as light emitting device 200 or 1000 to emit coherent light. The methods of control of the photonic band structure described herein, including the selective placement of one or more defects or aperiodic characteristics in a periodic photonic structure may be employed to separate a low-loss photonic mode from the other photonic states, wherein stimulated emission will result in the dominance of the separated mode due to its enhanced overlap with the electroluminescence spectrum of the emitter material relative to the other photonic modes. In this way, the methods described herein may be employed to produce a coherent light source, when the device is driven with a current density above the critical lasing threshold, or a high-intensity, incoherent, narrow-linewidth, single mode source, if driven below the critical lasing threshold. In another example of the invention, a selected number of states are separated from the other photonic modes and enhanced via stimulated emission, such as a dual-mode or tri-mode source.

FIG. 10 shows another example of a light emitting device 1000 that is an example implementation of lighting device 100 and includes a periodic one dimensional array of photonic unit cells 1002a-1002f that include emitters 1006a-1006f separated by electrodes 1004a-1004g, with adjacent emitters sharing a common electrode. The emitters 206 and electrodes 1004 are stacked in a vertical arrangement on a substrate 1008, with each of the emitters 1006 independently electrically driven by an electrical power source 1010. In the illustrated example, each of electrodes 1004 are transparent and may be formed from any of a variety of materials known in the art and that are optically transparent to the light emitted by emitters 1006, such as a high refractive index transparent material, such as indium tin oxide (ITO), titanium dioxide (TiO₂), tin dioxide (SnO₂), or zinc oxide (ZnO). Emitters 1006 may be any of the types of emitters disclosed herein, including any type of OLED emitter known in the art. In the illustrated example, device 1000 includes six photonic unit cells 1002 in a stacked arrangement, however, in other examples, any number of photonic unit cells, for example, greater than 2 photonic unit cells, and in some examples greater than 20 photonic unit cells, and in some examples between 2 and 20 photonic unit cells, and in some examples, between 2 and 15 photonic unit cells, and in some examples, between 2 and 10 photonic unit cells, and in some examples, between 2 and 6 photonic unit cells may be used, and in some examples between 3 and 20 photonic unit cells, and in some examples, between 3 and 15 photonic unit cells, and in some examples, between 3 and 10 photonic unit cells, and in some examples, between 3 and 6 photonic unit cells may be used, and in some examples between 4 and 20 photonic unit cells, and in some examples, between 4 and 15 photonic unit cells, and in some examples, between 4 and 10 photonic unit cells, and in some examples, between 4 and 6 photonic unit cells may be used.

Light emitting device 1000 is a Bragg-type structure having a one dimensional periodic array that includes multiple layers of alternating materials with varying refractive index and/or other characteristic, resulting in periodic variation in the effective refractive index in device 1000 similar to a distributed Bragg reflector. Partial reflections at the interfaces between emitters 1006 and electrodes 1004 due to the change in index of refraction produce a similar resonant condition as that produced by microcavities 202 in device 200. In the illustrated example, the fundamental emission wavelength occurs at 4 times the OPL of the photonic unit cell 1002 (rather than 2 times in a microcavity such as microcavities 202). In other examples, multiples of the fundamental λ/4 Bragg resonance are chosen, such as λ/2, 3λ/4 or λ modes, wherein the OPL of the OLED and high-index transparent electrodes are 2, 3 and 4 times that of the λ/4 mode, respectively. In some examples, the higher fundamental emission wavelength of device 1000 as compared to device 200 allows for thinner emitter devices, which can result in reduced electrical losses. Device 1000 also has significantly lower optical losses as compared to device 200 because of the removal of partially reflective mirrors, which can result in the emission intensity from device 1000 being over 100-1000×greater than for an equivalent device 200. In some examples, device 1000 may include a capping mirror 1012 on top of outer electrode 204g, the capping mirror being designed and configured for fine control over the quality factor (Q-factor) of the device 1000. The presence of capping mirror 1012 defines a single large microcavity between the bottom-most reflective electrode and the capping mirror, wherein the alternating series of emitters and high-index transparent electrodes constitutes a distributed feedback, distributed gain structure. In this way, the high Q-factor of a large multi-order microcavity may be combined with the low losses of the Bragg structure and enable direct electrical stimulation of the distributed emitter devices.

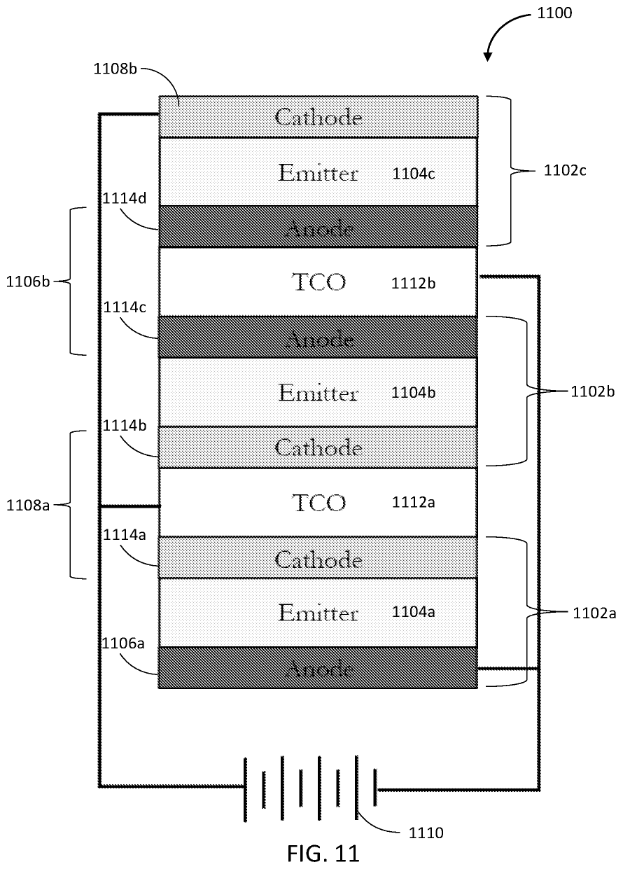

FIG. 11 shows another example of a light emitting device 1100 that is an example implementation of lighting device 100 and includes a periodic one dimensional array of microcavities 1102, here three microcavities 1102a-1102c, that include emitters 1104a-1104c, anodes 1106a, 1106b, and cathodes 1108a, 1108b. The emitters 1104 are independently electrically driven by an electrical power source 1110. In the illustrated example, as with device 100, adjacent microcavities share a common electrode. In the illustrated example, the common electrode between adjacent micro cavities 1102 includes a transparent and electrically conductive layer, such as a transparent conductive oxide (TCO) layer 1112a, 1112b sandwiched between metal electrode layers 1114a-1114d. As noted elsewhere in this disclosure, the optical performance of a stacked microcavity device can improve in some cases when the thickness of the semitransparent metal electrode layer is reduced. The layered cathode 1108a and anode 1106b can allow for extremely thin metal layers 1114a-1114d, e.g., less than 10 nm thickness, for improved optical performance while maintaining a thicker overall electrode to maintain or reduce electrical resistance. Unlike sputtering TCO on organics, the metal electrode films 1114 may be more robust and enable easier TCO deposition. The added TCO layers 1112 may also improve electrical performance and act as a heat sink.

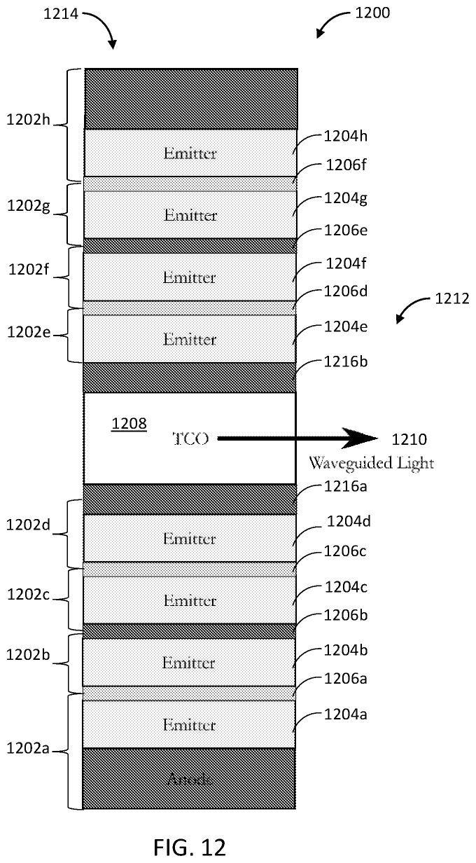

FIG. 12 shows another example of a light emitting device 1200 that comprises a plurality of microcavities 1202 stacked in a one-dimensional array, each of the microcavities including an emitter 1204, and adjacent microcavities sharing a common semitransparent or transparent electrode 1206 for directly electrically driving each emitter by one or more power sources (not illustrated). Device 1200 also includes at least one outcoupling cavity 1208, which may be transparent and that is designed and configured as a waveguide for extracting waveguided light 1210 from the side 1212 rather than through the top mirror 1214 of the device. The mirrors 1216 and 1214 may have the same or a different thickness than electrodes 1206.

Devices fabricated in accordance with the present disclosure may be designed and configured as coherent or incoherent light sources. In some examples, a plurality of light emitting devices, such as a plurality of device 200 or device 1000 may be used to form a display or light emitting device in a wide variety of consumer products, including flat panel displays, computer monitors, televisions, billboards, lights for interior or exterior illumination and/or signaling, heads up displays, fully transparent displays, flexible displays, laser printers, mobile computing devices, smartphones, telephones, cell phones, laptop computers, digital cameras, camcorders, viewfinders, micro-displays, vehicles, a large area wall, theater or stadium screen, or a sign, etc. Devices such as light emitting device 200 or 1000 designed to emit incoherent light with a narrow linewidth (e.g. (˜10⁻¹ nm) may also be used in spectroscopic applications.

In some examples, light emitting device 200 or light emitting device 1000 may be designed as a coherent light source, i.e., a laser and may emit light that is substantially monochromatic, e.g., have sub-nanometer linewidth; have spatial coherence, e.g., an output consisting of a single beam; have temporal coherence, e.g., have a measurable coherence time; exhibit clear threshold behavior in linewidth and power output; exhibit laser speckle, have a sensitive dependence on cavity resonator, and/or have high-order coherence. As is known in the art, the transition from incoherent to coherent occurs when passing the lasing threshold, a critical level of power density when the optical gain within the laser cavity exceeds the optical losses, and the power output exhibits a dramatically increased dependence on the input power. At the lasing threshold, stimulated emission exceeds spontaneous emission, and the emitting dipoles essentially emit light in phase with each other to contribute to a single beam rather than a random glow. In a continuous-wave (CW) laser, this coherence is sustained over a time scale called the coherence time, which quantifies the average time between a spontaneous phase shift. In order to maintain stability, continuous wave lasers generally have lower power output, particularly with traditional organic lasers due to the ease of burnout. Alternatively, a pulsed, electrically pumped laser operates on short time scales (nanoseconds to microseconds) and can achieve extremely high power output during that time.

In one example, a light emitting device made in accordance with the present disclosure, such as light emitting device 200 or light emitting device 1000 may be designed and configured as a CW laser designed to operate with a direct current driving voltage. In some examples, electronic pulse operation may be used to reach the lasing threshold, including microsecond pulses that achieve >3 kA/cm² current densities. Emitters, such as emitters 2006 or 1006 may have a construction designed for either CW or pulse laser operation and may include a guest-host matrix emitter with organic emitters and triplet managers such as those described in Zhang, Y. and Forrest, S. R., “Existence of Continuous-Wave Threshold for Organic Semiconductor Lasers,” Physical Review B 84, no. 24 (2011): 241301-4. doi:10.1103/PhysRevB.84.241301; and Sandanayaka, A. S. D., Zhao, L., Pitrat, D., Mulatier, J.-C., Matsushima, T., Andraud, C., Kim, J.-H., Ribierre, J.-C., and Adachi, C., “Improvement of the Quasi-Continuous-Wave Lasing Properties in Organic Semiconductor Lasers Using Oxygen as Triplet Quencher,” Applied Physics Letters 108, no. 22 (2016): 223301. doi:10.1063/1.4952970, each of which are incorporated by reference herein in their entireties. As is known in the art, a limiting factor for CW laser operation is triplet buildup. Triplets are electronic states in molecules which are long-lived, absorptive and do not emit light. Singlets are short-lived electronic states which can emit light. Due to spin statistics, electrically injected carriers form triplets and singlets in a 3:1 ratio. That is, an injected charge forms a singlet state 25% of the time. Since the triplets have a longer lifetime, this results in a buildup of absorbing, dark charges in the emitter layer which greatly increases the optical losses in the device. Triplet managers introduce energy pathways for triplets to collapse more quickly.

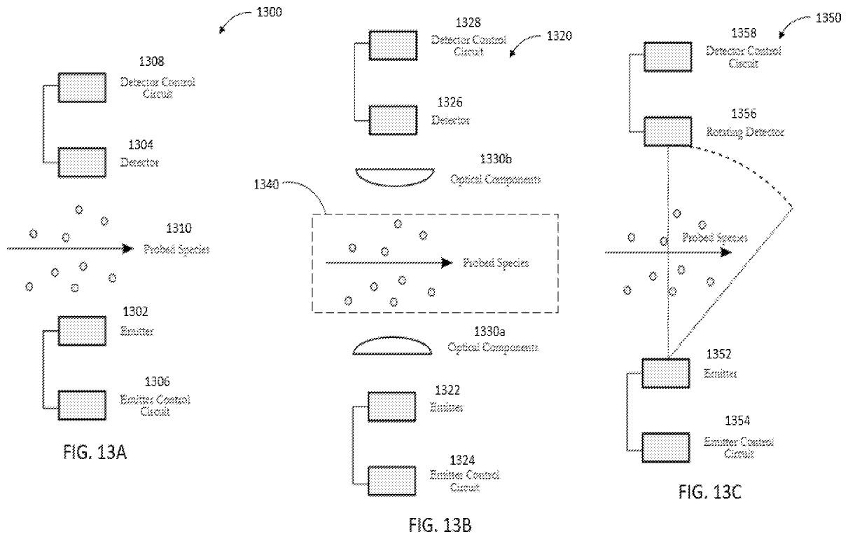

FIG. 13A illustrates one example of a transmission spectroscopy system 1300 made in accordance with the present disclosure. In the illustrated example, system 1300 includes an emitter 1302 configured to emit particular wavelengths of radiation, such as visible or infrared light, a detector 1304 configured to detect incident radiation, and controllers 1306 and 1308 for controlling the emitter and detector, the controllers being configured with any functionality known in the art of emitter and detector controllers in spectroscopic systems.

In the illustrated example, emitter 1302 and/or detector 1304 may include one or more stacked microcavity devices made in accordance with the present disclosure, such as an instantiation of any of the light emitting devices disclosed herein. The emitter 1302 may be tuned to particular wavelengths and configured to emit radiation through a sample 1310, where it interacts via absorption, reflection, diffraction, photoluminescence, refraction, etc. and the remaining or amplified radiation is collected on the other side by the detector 1304. Detector 1304 may be tuned to the same wavelength or range of wavelengths as the emitter 1302, a different wavelength or range of wavelengths, or may be wavelength independent (e.g., absorbs a broad spectrum of radiation). The probed species 1310 may be stationary or flowing and in any phase (solid, liquid, gas, plasma). The probed species 1310 could be a thin semi-transparent splice of a solid material, a collection of powder, a single crystal or several crystals, or a flowing or stationary fluid (including water, blood, blood plasma, liquid or gaseous hydrocarbons, solvents, coolant, hydraulic fluid, bodily fluids, air and other gases, plasma, etc.). The probed species 1310 may be in its ground state or an excited state.

FIG. 13B illustrates a transmission spectroscopy system 1320 that includes an emitter 1322, emitter controller 1324, detector 1326, and detector controller 1328 that may have the same or similar construction as in system 1300, including utilizing stacked arrays of microcavities made in accordance with the present disclosure, such as one or more of an instantiation of any of the light emitting devices disclosed herein, for emitter 1322 and/or detector 1326. System 1320 also includes optical components 1330a, 1330b to shape and control the beam of radiation emitted by emitter 1322 and radiation incident on detector 1326. For example, optical component 1330 may be designed and configured to receive light emitted by a stacked array of microcavities and emit monochromatic light. Any optical components known in the art may be utilized, such as one or more of optical fibers, lenses, polarizers, mirrors, beam splitters, phase plates, wave plates, birefringent crystals, dichroic filters, diffraction grating, and nonlinear optics including second harmonic generation, frequency doubling and frequency addition apparatus. These components may be any size and may be used in combination.

In one example application of system 1320, emitter 1322 and emitter controller 1324 may be located outside of a flow reactor 1340. The emitted light may pass through a polarizing filter and then be coupled into an optical fiber. The fiber may be attached to the side of the flow reactor to direct the light into the chamber. A similar setup may be repeated on the far side with the detector 1326 to collect the light after it has passed through the chamber.

FIG. 13C illustrates a transmission spectroscopy system 1350 that includes an emitter 1352, emitter controller 1354, detector 1356, and detector controller 1358 that may have the same or similar construction as in system 1300 or system 1320, including utilizing stacked arrays of microcavities made in accordance with the present disclosure, for emitter 1352 and/or detector 1356. System 1350 may also include one or more optical components similar to system 1320. In the illustrated example, either the detector 1356 or emitter 1352 or both may be mounted on a rotating apparatus, which allows access to different wavelengths due to dispersion of light output from the stacked microcavities of the emitter 1352. As an example, the dispersion of light emitted by a stacked microcavity device made in accordance with the present disclosure may have a peak emission at, for example, 550 nm at 0° but shift to 450 nm at 60°. This dispersion can utilized for spectroscopic measurements using system 1350.

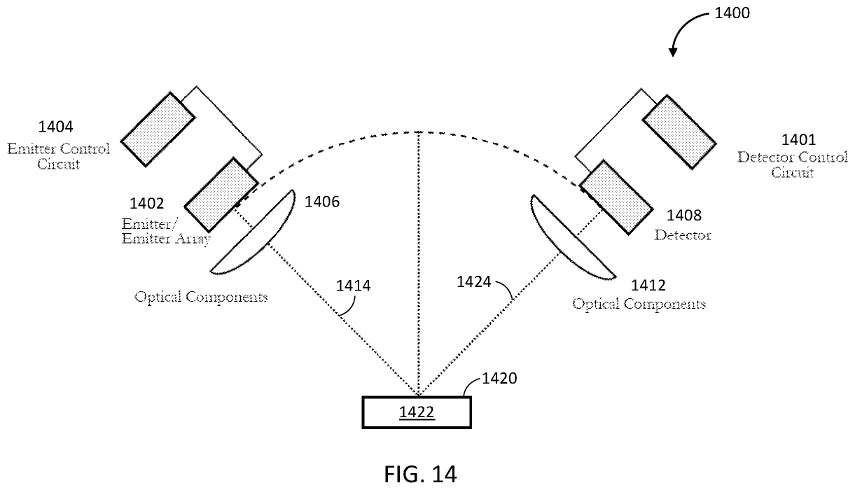

FIG. 14 illustrates one example of a reflection spectroscopy or reflection imaging system 1400 made in accordance with the present disclosure. System 1400 includes an emitter 1402 (or an array of emitters), an emitter controller 1404, and optical components 1406 configured to emit one or more specific wavelengths of radiation, the emitter 1402 including one or more stacked arrays of microcavities made in accordance with the present disclosure. System 1400 also includes a detector 1408, detector controller 1410, and optical components 1412. The radiation 1414 emitted from emitter 1402 is shined onto a surface 1420 of a sample 1422 where it interacts via absorption, reflection, diffraction, photoluminescence, refraction, etc. and the reflected light 1424 is detected by detector 1408 located outside of the original beam path. System 1400 may be used for ellipsometry and diffraction, among other applications. The emitter 1402, detector 1408, and sample 1422 may all be mounted to enable rotation through different angles of incidence and reflection on the sample.

FIG. 15 is an imaging system 1500 that has a similar configuration as system 1400 and may include an emitter 1502 (or an array of emitters), an emitter controller 1504, optical components 1506 configured to emit one or more specific wavelengths of radiation, the emitter 1502 including one or more stacked arrays of microcavities made in accordance with the present disclosure. System 1500 also includes a detector 1508, detector controller 1510, and optical components 1512. Unlike system 1400, in system 1500 the detector 1508 is located normal to a surface 1520 of a sample 1522 for imaging the surface of the sample. The emitter 1502 is configured to provide illumination for the imaging system.

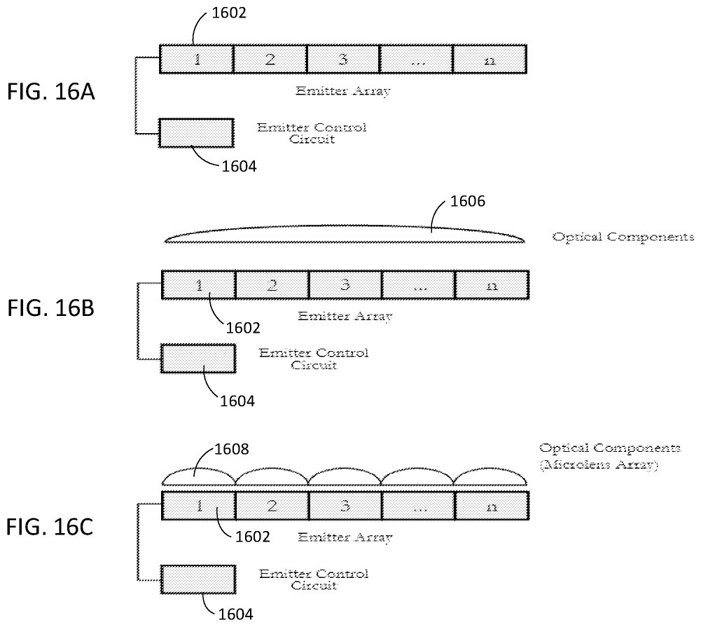

FIGS. 16A-16C illustrate three examples of arrays of emitters 1602 (only one labeled in each array), where each emitter includes at least one stacked array of microcavities made in accordance with the present disclosure. The emitters 1602 may be arranged in a one or two dimensional array to form any kind of display or diode array known in the art. For example, emitters 1602 may include groupings of diodes, where each diode emits a different color, such as red, green, and blue, to form a pixel of the display as is well known in the art of displays. Any type of diode grouping and packaging known in the art of displays may be utilized. In the forgoing example, at least one of the red, green, or blue diodes may include at least one stacked array of microcavities, such as device 100 or any of the other light emitting devices disclosed herein. Each example includes at least one controller 1604 that may have any configuration known in the art of displays, such as OLED displays. The examples illustrated in FIGS. 16B and 16C also include one or more optical components 1606, 1608 to perform any optical function known in the art. Optical components 1608 (only one labeled) in the example shown in FIG. 16C are microlenses and form a microlens array. Each microlens may be fabricated on top of each individual emitter 1602 to enhance light outcoupling and control the angular emission profile of the emitter.

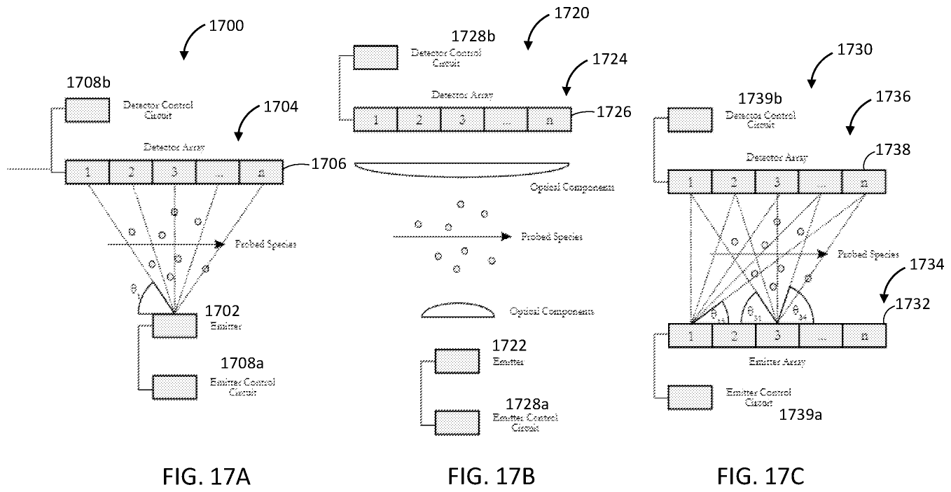

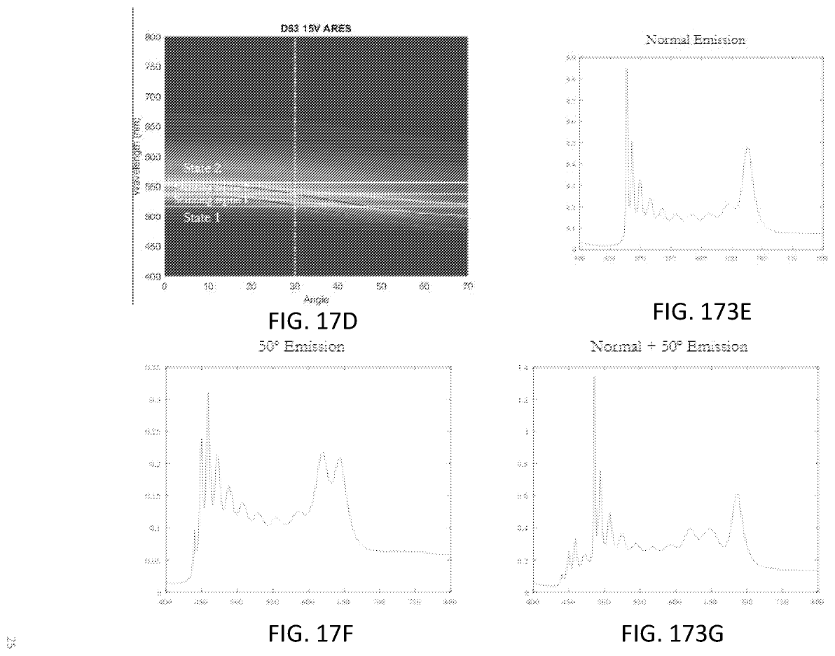

FIGS. 17A-17C illustrate three examples of angle-resolved transmission spectroscopy systems 1700, 1720, and 1730 that utilize the dispersion in the angular emission from stacked microcavity emitters 1702, 1722, 1732, to probe multiple wavelengths simultaneously and allow a low fidelity scan. Each of emitters 1702, 1722, 1732 include at least one stacked array of microcavities made in accordance with the present disclosure. Systems 1700 and 1720 have a similar construction, including an array 1704, 1724 of detectors 1706, 1726 (only one labeled), each detector positioned at a different location relative to emitter 1702/1722 to leverage the dispersion of the emitters and capture the effect of the alternate wavelength of radiation emitted from various positions around each stacked array of microcavities. System 1720 further includes one or more optical components, which may include any of the optical components disclosed herein to shape and control the radiation emitted by the emitters and incident on the detectors.

System 1730 shown in FIG. 17C has an array 1734 of emitters 1732 that are positioned across from a corresponding array 1736 of detectors 1738. As indicated in FIG. 17C, the detectors 1738 may be configured to capture light emitted from a plurality of the emitters 1732 to similarly leverage the dispersion characteristic of the emitters.

FIG. 17D illustrates one example of the dispersion exhibited by an example emitter, such as emitter 1702, 1722, or one of emitters 1732. The ARES spectrum illustrated in FIG. 17D shows two scanning regions of wavelength and angle where there is only one emission peak. Through these regions, the peak wavelength of the state shifts to shorter wavelength. By scanning across the angular range, variations in the light interaction can be obtained. FIGS. 17E-G illustrate emission cross sections of three emission spectra: one at 0° (FIG. 17E), one at 500 (FIG. 17F) and then an example of the sum of the two (FIG. 17G). The third spectrum illustrated in FIG. 17G represents the effective emission spectrum seen by a detector at 50° to one emitter 1602/1622/1632 and 0° to a second emitter. As can be seen, this allows a greater scanning range than simply having a single emitter (a scanning range from 450 nm to 700 nm in FIG. 17G instead of 475 nm to 700 nm in FIGS. 17E ad 17F). The amount of dispersion controls this shift, as high dispersion will allow a greater change in wavelength with angle and hence a greater effective scanning range. This characteristic of angle dependent wavelength is utilized in each of systems 1700, 1720, and 1730. In each of systems 1700, 1720, and 1730 the detectors and/or emitters may be moveable, such as rotatable to change the relative positioning between the emitters and detectors. As shown, each of systems 1700, 1720, and 1730 include controllers 1708a, 1708b; 1728a, 1728b; 1739a, 1739b for controlling the emitters and detectors and that may have any configuration known in the art of emitter and detector controllers.

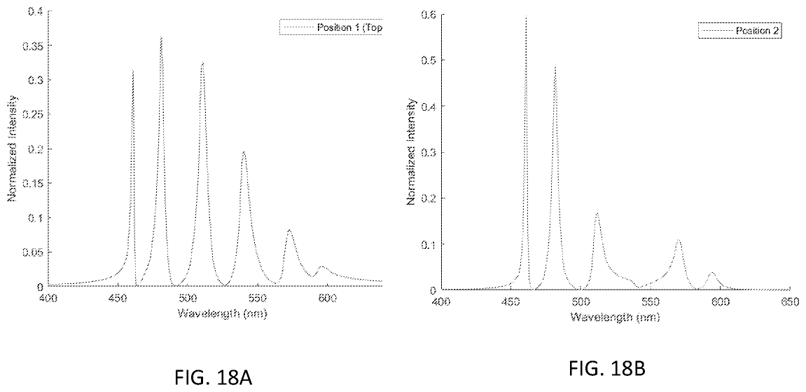

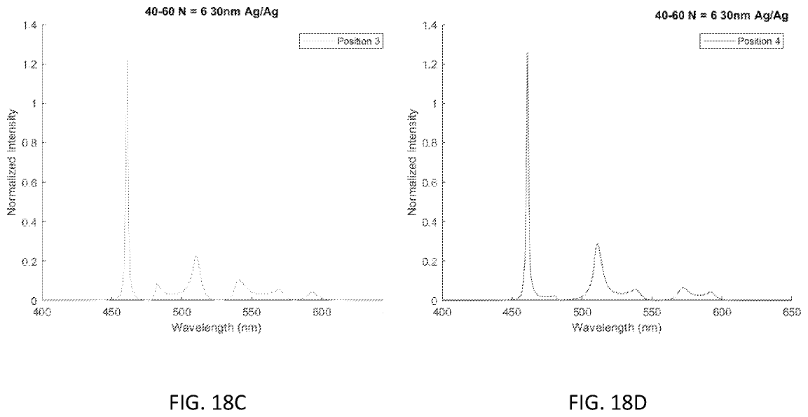

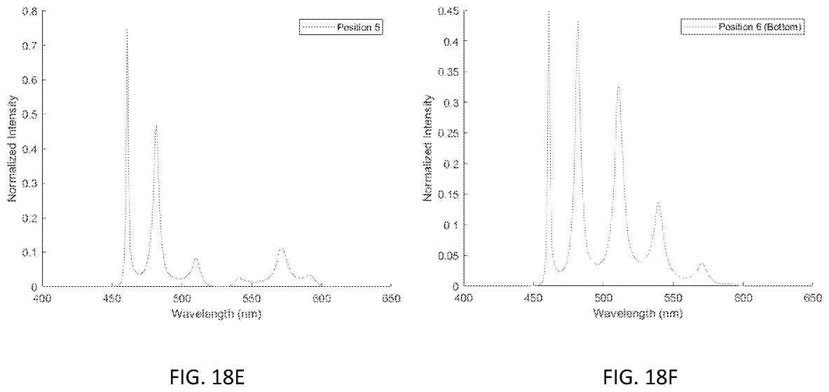

FIGS. 18A-18F illustrate a further method of control over the emission characteristics of an example instantiation of six cavity device 200, wherein the microcavities 202 within the photonic structure are selectively activated. In one example, even though each of the emitters 206 within six cavity device 200 are the same, they each exhibit a different distribution of emission among the resonant photonic states of the structure due to their location within the structure. FIG. 18A shows the emission distribution when only the top-most emitter 206f is activated while the other emitters are not activated and not emitting light. FIG. 18A shows a roughly equal emission among the resonant states. FIG. 18B shows the emission from the device 200 when only the fifth emitter 206e, located in microcavity 202e (one cavity below the top-most cavity), wherein the emitter preferentially emits into the highest-energy mode but also emits in the other modes. FIGS. 18C-D show the emission when only the fourth emitter 206d or third emitter 206c, respectively (located two and three cavities below the top-most microcavity 202f) are electrically driven. In both instances the emitter strongly prefers to emit in the highest energy mode, the other modes being suppressed. FIG. 18E shows the emission when only the second emitter 206b (located one cavity above the bottom-most cavity 202a) is electrically activated. As shown in FIG. 18E, emitter 206b preferentially emits in the two highest energy modes, the other modes being suppressed. FIG. 18F shows the emission from the bottom-most emitter 206a, wherein the emitter emits in all resonant modes roughly equally. In other examples, any combination of two or more of the emitters 206 can be selectively activated to achieve a desired emission characteristic. As illustrated in FIGS. 18A-18F, by activating one or more of the emitters 206, certain modes can be promoted or suppressed. Thus, by activating only emitters 206c and 206d (emitters 3 and 4) (FIGS. 18C and D), the highest energy mode might be enhanced relative to the other modes. In another example, only the top-most emitter, e.g., emitter 206f might be activated to provide a more even distribution of emission among the resonant states.

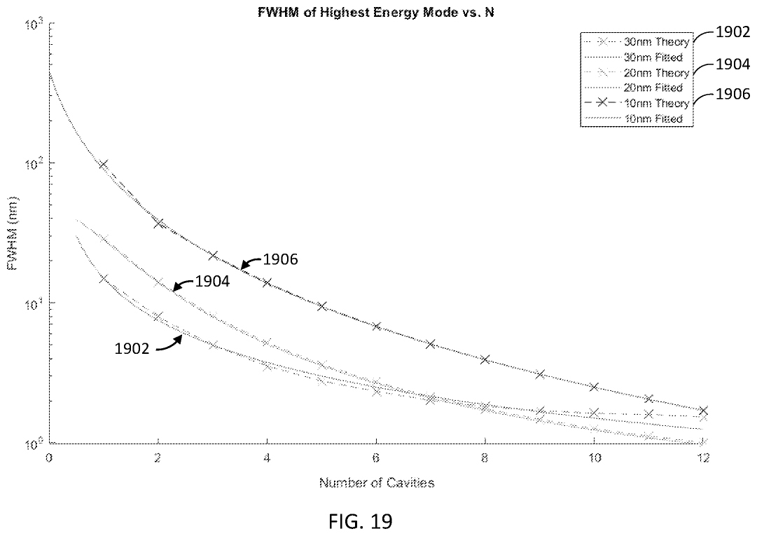

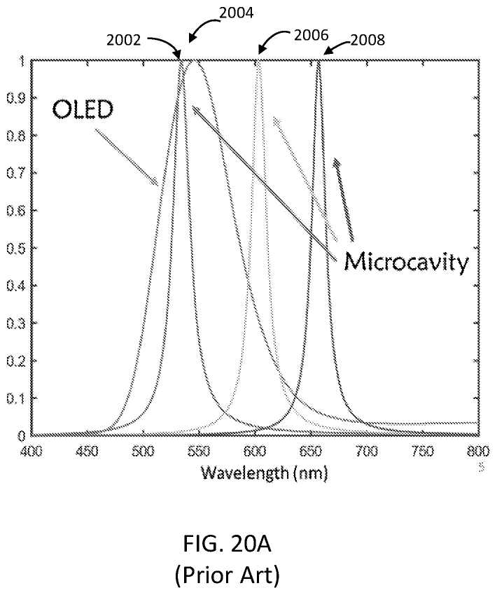

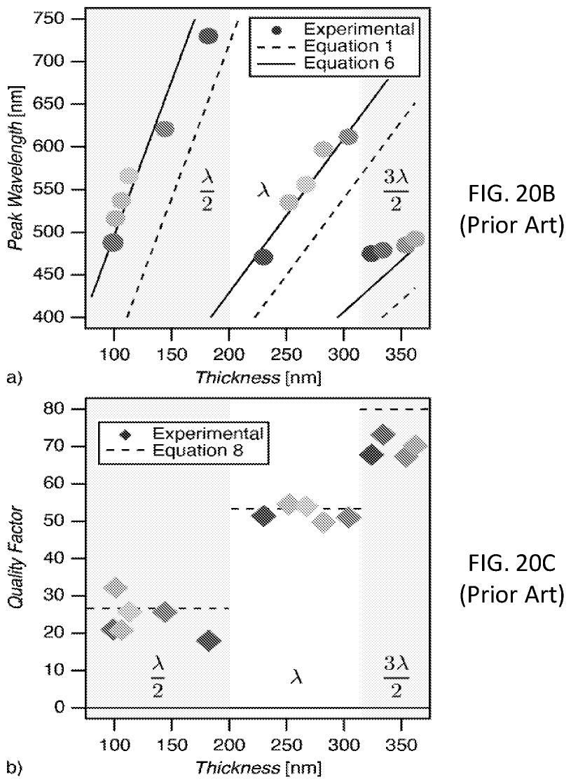

FIG. 19 demonstrates the reduction in the FWHM of the highest-energy mode in an ideal photonic structure as a function of the number of cavities (e.g. number of microcavities 202) and the electrode (or other semitransparent layer) thickness (e.g. thickness of electrodes 204) for devices with 30 nm mirrors (1902), 20 nm mirrors (1904) and 10 nm mirrors (1906). FIG. 19 includes illustrates the FWHM for the highest-energy mode for devices. As shown, the FWHM of the highest energy mode exhibits a dependence on the mirror thickness and other structural characteristics of the photonic structure as well as the number of cavities. Thus, it is possible to choose a number of cavities and a set of structural characteristics to achieve a particular FWHM. In this way, and in combination with the use of aperiodicities and electrical control described herein, it is possible to design all aspects of the emission spectrum by varying the periodicity and structural characteristics of the photonic structure.

The foregoing has been a detailed description of illustrative embodiments of the disclosure. It is noted that in the present specification and claims appended hereto, conjunctive language such as is used in the phrases “at least one of X, Y and Z” and “one or more of X, Y, and Z,” unless specifically stated or indicated otherwise, shall be taken to mean that each item in the conjunctive list can be present in any number exclusive of every other item in the list or in any number in combination with any or all other item(s) in the conjunctive list, each of which may also be present in any number. Applying this general rule, the conjunctive phrases in the foregoing examples in which the conjunctive list consists of X, Y, and Z shall each encompass: one or more of X; one or more of Y; one or more of Z; one or more of X and one or more of Y; one or more of Y and one or more of Z; one or more of X and one or more of Z; and one or more of X, one or more of Y and one or more of Z.

Various modifications and additions can be made without departing from the spirit and scope of this disclosure. Features of each of the various embodiments described above may be combined with features of other described embodiments as appropriate in order to provide a multiplicity of feature combinations in associated new embodiments. For example, any of light emitting devices 100, 200, 1000, 1100, or 1200 may be utilized in any of the applications and systems disclosed herein, such as the systems illustrated in FIGS. 13A-17C. The particular characteristics and possible modifications of any of of light emitting devices 100, 200, 1000, 1100, or 1200 described herein may be applied to any of the light emitting devices disclosed herein by a person having ordinary skill in the art after reading the present disclosure. Furthermore, while the foregoing describes a number of separate embodiments, what has been described herein is merely illustrative of the application of the principles of the present disclosure. Additionally, although particular methods herein may be illustrated and/or described as being performed in a specific order, the ordering is highly variable within ordinary skill to achieve aspects of the present disclosure. Accordingly, this description is meant to be taken only by way of example, and not to otherwise limit the scope of this disclosure.

1. (canceled)

2.-47. (canceled)

48. A light emitting device, comprising:
a substrate; and
a photonic structure disposed on the substrate, the photonic structure comprising a one-dimensional array of a plurality of photonic unit cells;
wherein each of the photonic unit cells comprises at least one metallic layer and at least one dielectric layer, wherein at least one of the photonic unit cells emits photons in response to an applied electrical stimulus.

49. The light emitting device of claim 48, further comprising a back reflector located between the substrate and the photonic structure.

50. The light emitting device of claim 49, wherein the back reflector is one of, or a combination of, a metallic mirror, a distributed Bragg reflector, an adhesion layer, a conductor, a thermal conductance layer, or a thermal dissipation layer.

51. The light emitting device of claim 48, wherein the substrate is comprised of one of, or a combination of, silicon, a polymeric material, sapphire, an organic material, a ceramic material, a glass material, a metallic material, a flexible material, a semiconducting material, an insulating material, an integrated circuit, and a waveguide.

52. The light emitting device of claim 48, further comprising a capping mirror formed on the plurality of photonic unit cells.

53. The light emitting device of claim 52, wherein the capping mirror is one of, or a combination of, a metallic mirror, a distributed Bragg reflector, a phase-matching layer, an index-matching layer, and an out-coupling layer.

54. The light emitting device of claim 48, wherein each of the plurality of photonic unit cells includes one or more microcavities, wherein a ratio of a total thickness of the at least one metal layer to a total thicknesses of the at least one dielectric layer in a given one of the microcavities is between 0.05 and 1.14.

55. The light emitting device of claim 48, wherein the photonic unit cells emit photons having a photonic band structure, wherein a combined optical pathlength of the at least one dielectric layer within one of the photonic unit cells is at least half of a center wavelength of the photonic band structure.

56. The light emitting device of claim 48, further comprising an optically active layer.

57. The light emitting device of claim 56, wherein the optically active layer includes at least one of integrated non-linear optics, Kerr electro-optic effect for mode-locking, Q-switching layer, or a saturable absorber.

58. The light emitting device of claim 48, wherein each photonic unit cell includes at least two microcavities.

59. The light emitting device of claim 48, wherein the at least one layer that emits photons is comprised of at least one of:
one or more types of organic molecules;
one or more types of organic molecules doped with one or more dopants;
one or more types of polymers;
one or more types of polymers doped with one or more dopants;
one or more types of perovskite materials;
one or more types of perovskite materials doped with one or more dopants;
one or more types of semiconductor materials; or
one or more types of semiconductor materials doped with one or more dopants;
wherein said the dopants are at least one of an organic dye, a laser dye, an inorganic molecule, or a chemical element.

60. The light emitting device of claim 48, wherein the at least one dielectric layer is an OLED.

61. The light emitting device of claim 60, wherein the OLEDs emit photons in response to electrical stimulus applied through corresponding respective ones of said the at least one metallic layer.

62. The light emitting device of claim 48, wherein the photonic structure includes at least one non-periodic aperiodicity.

63. The light emitting device of claim 62, wherein the non-periodic aperiodicity is a topological aperiodicity.

64. The light emitting device of claim 63, wherein the non-periodic aperiodicity comprises at least one dielectric layer that has a different characteristic than the at least one dielectric layers in other ones of the photonic unit cells.

65. The light emitting device of claim 63, wherein the non-periodic aperiodicity comprises at least one metallic layer that has a different characteristic than the at least one metallic layers in other ones of the photonic unit cells.

66. A light emitting device, comprising:
a photonic structure that includes a plurality of photonic unit cells, wherein each of the plurality of photonic unit cells includes one or more microcavities, each of the microcavities including two parallel semitransparent mirrors and an electrically driven emitter located therebetween, each of the microcavities designed and configured to have at least one resonant mode, wherein the semitransparent mirrors are designed and configured to allow interaction of the at least one resonant modes of adjacent ones of the microcavities.

67. The light emitting device of claim 66, wherein the semitransparent mirrors are electrodes and transmit current for electrically driving the emitters, wherein the electrodes include anodes and cathodes, wherein at least one optical characteristic of the anodes and cathodes are different, the optical characteristics designed and configured to create a perturbation in a photonic band structure of the device.

68. The light emitting device of claim 66, wherein an optical path length (OPL) of a first one of the microcavities is different than an OPL of other ones of the microcavities, the OPL of the first microcavity designed and configured to create a perturbation in an emission profile of the device to suppress a first portion of wavelengths of light and/or promote a second portion of wavelengths of light.

69. A light emitting device, comprising:
a substrate;
a bottom mirror disposed on said substrate;
an alternating series of high and low index materials disposed on said bottom mirror; and
a top mirror deposited on said alternating series;
wherein said low index materials are layers of light emitting diodes that are optically emissive in response to electrical stimulus provided through said high index materials.

70. The light emitting device of claim 69, wherein the high index materials are transparent electrodes.
